(19) United States
(12) Patent Application Publication
(10) Pub. No.: US 2026/0129871 A1
(43) Pub. Date: May 7, 2026

(54) NONVOLATILE MEMORY DEVICES USING ION REDISTRIBUTION AND METHODS OF MANUFACTURING THE SAME AND ELECTRONIC APPARATUSES INCLUDING NONVOLATILE MEMORY DEVICE

(71) Applicant: Samsung Electronics Co., Ltd., Suwon-si (KR)

(72) Inventors: Sunho KIM, Suwon-si (KR); Minhyun LEE, Suwon-si (KR); Garam PARK, Suwon-si (KR)

(73) Assignee: Samsung Electronics Co., Ltd., Suwon-si (KR)

(21) Appl. No.: 19/376,344

(22) Filed: Oct. 31, 2025

(30) Foreign Application Priority Data
Nov. 1, 2024 (KR) 10-2024-0153786

(51) Int. Cl. H10B 63/00; H10N 70/00; H10N 70/20

(52) U.S. Cl. CPC H10B 63/845; H10N 70/066; H10N 70/245; H10N 70/253

(57) ABSTRACT

Disclosed are a nonvolatile memory device utilizing ion redistribution and a method of manufacturing the same and an electronic apparatus including the nonvolatile memory device. A memory device according to at least one example embodiment includes a first semiconductor layer including a channel, and a gate stack provided on the channel of the first semiconductor layer. The gate stack includes an electrolyte layer including mobile ions, a distribution state of which changes depending on an applied voltage, and first and second barrier layers disposed facing each other with the electrolyte layer therebetween.

### CROSS-REFERENCE TO RELATED APPLICATION

This application is based on and claims priority under 35 U.S.C. §119 to Korean Patent Application No. 10-2024-0153786, filed on Nov. 1, 2024, in the Korean Intellectual Property Office, the disclosure of which is incorporated by reference herein in its entirety.

### BACKGROUND

### 1. Field

The disclosure relates to a memory device and a method of manufacturing the same, and more specifically, to a nonvolatile memory device using ion redistribution and a method of manufacturing the same, and an electronic apparatus including the nonvolatile memory device.

### 2. Description of the Related Art

Semiconductor devices may be configured as memory devices and/or logic devices. Memory devices are devices that are configured to store data. Generally, semiconductor memory devices may be mainly classified into volatile memory devices and nonvolatile memory devices. Volatile memory devices are memory devices in which stored data disappears when power thereto is cut off, such as dynamic random access memory (DRAM) and static random access memory (SRAM). Nonvolatile memory devices are memory devices in which stored data does not disappear when power is cut off, such as programmable ROM (PROM), erasable PROM (EPROM), electrically EPROM (EEPROM), and/or flash memory devices.

In addition, in line with the recent trend of high performance and low power consumption of semiconductor memory devices, next-generation semiconductor memory devices such as magnetic RAM (MRAM), phase change RAM (PCRAM), and resistive RAM (ReRAM) are being developed. The next-generation semiconductor memory devices have characteristics in which their resistance values change depending on current, voltage, or heat, and their resistance values remain the same even when the current or voltage supply is cut off. Research is being conducted to apply these memories in the form of vertical NAND (VNAND). In the case of NAND flash products that currently dominate the memory market, VNAND products, which are advantageous for increasing integration, are the main items. However, these VNAND products are approaching the height limit allowable in current chip packaging, and thus, methods of scaling unit cells are being studied. Resistive VNANDs that utilize resistive memory exhibit a phenomenon in which electrons move through a shared charge trap layer during operation, which may deteriorate various characteristics of a memory.

### SUMMARY

Provided is a memory device having improved retention characteristics.

Provided is a memory device having improved integration.

Provided is a memory device having improved memory capacity.

Provided is a method of manufacturing the memory device.

Provided is an electronic apparatus including the memory device.

Additional aspects will be set forth in part in the description which follows and, in part, will be apparent from the description, or may be learned by practice of the presented embodiments of the disclosure.

According to an aspect of the disclosure, a memory device includes a first semiconductor layer including a channel and a gate stack on the channel of the first semiconductor layer. The gate stack may include an electrolyte layer including mobile ions configured such that the gate stack has an adjustable distribution state depending on an applied voltage, and a first barrier layer and a second barrier layer facing each other with the electrolyte layer therebetween, the first and second barrier layers configured to inhibit the mobile ions from diffusing out of the electrolyte layer.

In an example, a first auxiliary barrier layer may further be between the electrolyte layer and the first barrier layer, and a second auxiliary barrier layer may further be between the electrolyte layer and the second barrier layer.

In an example, a third auxiliary barrier layer may further be facing the electrolyte layer with the first barrier layer therebetween, and a fourth auxiliary barrier layer may further be facing the electrolyte layer with the second barrier layer therebetween.

In an example, the mobile ions may include alkali metal ions, alkali-earth metal ions, and/or a combination thereof.

In an example, the memory device may further include a second semiconductor layer, wherein the first semiconductor layer may be provided in a direction perpendicular to one surface of the second semiconductor layer, the gate stack may be included in a plurality of the gate stacks, and the plurality of gate stacks are stacked in the direction perpendicular to the one surface of the second semiconductor layer, and the channel may be shared by the plurality of gate stacks. The first barrier layer, the second barrier layer, and the electrolyte layer of each the plurality of gate stacks may be connected to the first barrier layer, the second barrier layer, and the electrolyte layer of a neighboring gate stack in the direction perpendicular to the one surface of the second semiconductor layer. In an example, the first barrier layer, the second barrier layer, and the electrolyte layer of each of the plurality of gate stacks are spaced apart from the first barrier layer, the second barrier layer, and the electrolyte layer of a neighboring gate stack in the direction perpendicular to the one surface of the second semiconductor layer. Each of the plurality of gate stacks may completely surround the first semiconductor layer, and the first barrier layer, the electrolyte layer, and the second barrier layer, may be concentric.

According to an aspect of the disclosure, a method of manufacturing a memory device, the method includes forming a stack structure by alternately depositing plurality of sacrificial layers and insulating layer, forming a channel hole penetrating the stack structure, sequentially forming a first barrier layer, an electrolyte layer including mobile ions, and a second barrier layer on an inner surface of the channel hole, filling at least a portion of an interior of the channel hole remaining after the first barrier layer, the electrolyte layer, and the second barrier layer are formed, with a semiconductor layer, removing the sacrificial layers to form gate holes, and depositing an electrode material in the gate holes.

In an example, the method may further include forming a first auxiliary barrier layer such that the first auxiliary barrier layer is between the electrolyte layer and the first barrier layer. The method may further include forming a second auxiliary barrier layer such that the second auxiliary barrier layer is between the electrolyte layer and the second barrier layer.

In an example, the method may further include forming a third auxiliary barrier layer such that the third auxiliary barrier layer is between the semiconductor layer and the first barrier layer. The method may further include forming a fourth auxiliary barrier layer such that the fourth auxiliary barrier layer is between the electrode material and the second barrier layer.

According to another aspect of the disclosure, a method of manufacturing a memory device, the method includes forming a stack structure by alternately depositing a plurality of sacrificial layers and mask layers;, forming a channel hole penetrating the stack structure, sequentially forming a first barrier layer, an electrolyte layer including mobile ions, and a second barrier layer on an inner surface of the channel hole, filling at least a portion of an interior of the channel hole remaining after the first barrier layer, the electrolyte layer, and the second barrier layer are formed, with a semiconductor layer, forming a hole through which the semiconductor layer is exposed by removing the sacrificial layers and portions of the first barrier layer, the electrolyte layer, and the second barrier layer between the sacrificial layers and the semiconductor layer, filling, with an insulating layer, the hole through which the semiconductor layer is exposed, removing the mask layers, and depositing an electrode material in regions where the mask layers are removed.

In an example, the method may further include forming at least one auxiliary barrier layer such that the at least one auxiliary barrier layer is on at least one of an inside or an outside of the first barrier layer and forming another at least one auxiliary barrier layer such that the at least one other auxiliary barrier layer is on at least one of an inside or outside of the second barrier layer.

According to an aspect of the disclosure, an electronic apparatus includes a memory and a memory controller configured to control an operation of the memory.

The memory may include a first semiconductor layer including a channel and a gate stack on the channel of the first semiconductor layer.

The gate stack may include an electrolyte layer including mobile ions configured such that the gate stack has an adjustable distribution state of depending on an applied voltage, and a first barrier layer and a second barrier layer facing each other with the electrolyte layer therebetween, the first and second barrier layers configured inhibit the mobile ions from diffusing out of the electrolyte layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view showing a first nonvolatile memory device according to at least one example embodiment;

FIG. 2 is a cross-sectional view showing a first memory cell array including a plurality of first nonvolatile memory devices according to at least one example embodiment;

FIG. 3 is a cross-sectional view showing a second memory cell array including a plurality of first nonvolatile memory devices according to at least one example embodiment;

FIG. 4 is a cross-sectional view showing a second nonvolatile memory device according to at least one example embodiment;

FIG. 5 is a cross-sectional view showing a third nonvolatile memory device according to at least one example embodiment;

FIGS. 6 and 7 are cross-sectional views showing an operating method of a nonvolatile memory device according to at least one example embodiment;

FIG. 8 is a cross-sectional view showing a fourth nonvolatile memory device which is a vertical-type memory cell according to at least one example embodiment;

FIG. 9 is a plan view taken along line 9-9′ of FIG. 8;

FIG. 10 is a plan view showing in detail an example of a gate stack configuration of FIG. 9;

FIG. 11 is a plan view showing a case when the plane shape of the gate electrode of FIG. 9 is a non-circular shape (e.g., square);

FIG. 12 is a cross-sectional view showing a VNAND including a nonvolatile memory device according to at least one example embodiment;

FIG. 13 is a cross-sectional view showing a cell string having a different configuration from the cell string of FIG. 12;

FIG. 14 is a three-dimensional view showing the cell string of FIG. 12;

FIG. 15 is a cross-sectional view showing a VNAND having a plurality of cell strings shown in FIG. 12;

FIG. 16 is an equivalent circuit diagram for the VNAND of FIG. 15;

FIGS. 17 to 21 are cross-sectional views showing a first manufacturing method of a first nonvolatile memory device step by step, according to at least one example embodiment;

FIGS. 22 to 30B are cross-sectional views and plan views showing a second manufacturing method of a nonvolatile memory device step by step, according to at least one example embodiment;

FIGS. 31 to 36 are cross-sectional views illustrating a third manufacturing method of a nonvolatile memory device step by step, according to at least one example embodiment;

FIG. 37 is a block diagram of a memory system according to at least one example embodiment; and

FIG. 38 is a block diagram showing a neuromorphic device and an external device connected to the neuromorphic device, according to at least one example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a nonvolatile memory device utilizing ion redistribution according to embodiments and a method of manufacturing the same and an electronic apparatus including the nonvolatile memory device will be described in detail with reference to the accompanying drawings.

The following embodiments described below are merely illustrative, and various modifications may be possible from the embodiments. In the drawings, like reference numerals refer to like elements, and in the drawings, sizes of constituent elements may be exaggerated for clarity and convenience of explanation.

Hereinafter, spatially relative terms, such as upper, lower, side, etc. are represented based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly. Additionally, when a position of an element is described using an expression “above” or “on”, the position of the element may include not only the element being “immediately on/under/left/right in a contact manner” but also being “on/under/left/right in a non-contact manner”.

Although the terms ‘first’, ‘second’, etc. may be used herein to describe various constituent elements, these terms are only used to distinguish one constituent element from another. These terms do not limit the material or structure of the constituent elements.

Singular forms include the plural forms unless the context clearly indicates otherwise. When a part “comprises” or “includes” an element in the specification, unless otherwise defined, it is not excluding other elements but may further include other elements. Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Further, whenever a range of values is enumerated, the range includes all values within the range as if recorded explicitly clearly, and may further include the boundaries of the range. Accordingly, a range of “X” to “Y” includes all values between X and Y, including X and Y, unless expressly indicated otherwise.

Also, in the specification, the term “units” or “...modules” denote units or modules that process at least one function or operation, and may be realized by processing circuitry, such as hardware, software, or a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc.

The term “above” and similar directional terms may be applied to both singular and plural.

With respect to operations that constitute a method, the operations may be performed in any appropriate sequence unless the sequence of operations is clearly described or unless the context clearly indicates otherwise. All example terms (for example, etc.) are simply used to explain in detail the technical scope of the disclosure, and thus, the scope of the disclosure is not limited by the examples or the example terms as long as it is not defined by the claims.

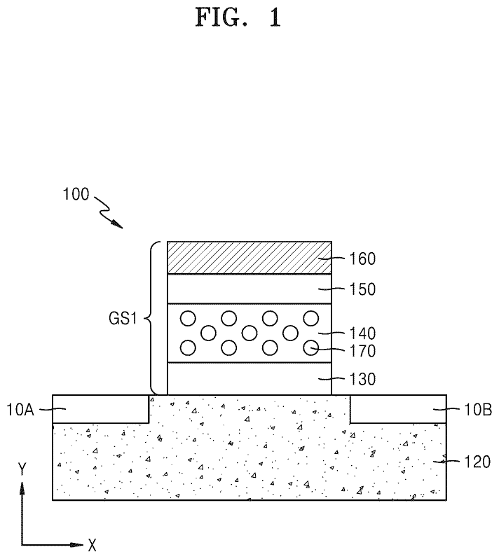

FIG. 1 shows a first nonvolatile memory device 100 using ion redistribution according to at least one example embodiment.

Referring to FIG. 1, the first nonvolatile memory device 100 includes a substrate 120 including a first doped region 10A and a second doped region 10B that are spaced apart from each other and includes a first gate stack GS1 provided on the substrate 120 between the first doped region 10A and the second doped region 10B. The first gate stack GS1 may be arranged to be spaced apart from the first and second doped regions 10A and 10B. For example, in at least one example, the side surfaces of the first gate stack GS1 may be spaced apart from the first doped region 10A and the second doped region 10B in a first direction (e.g., the X-axis direction) such that the first gate stack GS1 does not overlap with the first doped region 10A and/or the second doped regions 10B. In at least one example, the substrate 120 may be a first semiconductor layer including a semiconductor material (e.g., an elemental semiconductor such as silicon (Si) and/or a compound semiconductor) and/or may include the first semiconductor layer. In at least one example, the first semiconductor layer included in the substrate 120 may include a binary or higher compound semiconductor layer, for example, a compound semiconductor layer including a Group III-V element, but is not limited thereto. In at least one example, the first semiconductor layer included in the substrate 120 may include an oxide semiconductor layer. For example, the first semiconductor layer included in the substrate 120 may include a ternary or higher oxide semiconductor (for example, InGaZnO), but is not limited thereto. The substrate 120 may also be referred to as the first semiconductor, a first substrate, and/or a base substrate.

One of the first doped region 10A and the second doped region 10B may be a source region, and the other may be a drain region. For example, the first doped region 10A may be a source region where a source contact is formed, and the second doped region 10B may be a drain region where a drain contact is formed. In at least one example, the first and second doped regions 10A and 10B may be regions doped with a p-type conductive impurity or an n-type conductive impurity. A region between the first doped region 10A and the second doped region 10B in the first semiconductor layer included in the substrate 120 may be a channel or channel region through which carriers (such as electrons or holes) may flow. The first gate stack GS1 may be positioned on the channel. The first gate stack GS1 may have a layer structure including a first barrier layer 130, a recording layer 140, a second barrier layer 150, and a gate electrode layer 160 sequentially stacked on the first semiconductor layer included in the substrate 120 between the first doped region 10A and the second doped region 10B in a direction perpendicular to an upper surface of the first semiconductor layer included in the substrate 120 (e.g., the Y-axis direction). The first barrier layer 130, the recording layer 140, the second barrier layer 150, and the gate electrode layer 160 may or may not be in direct contact with each other. In at least one example, the entire facing surfaces of the first barrier layer 130, the recording layer 140, the second barrier layer 150, and the gate electrode layer 160 may be provided to contact each other. In at least one example, the first barrier layer 130, the recording layer 140, the second barrier layer 150, and the gate electrode layer 160 may or may not have the same width in a first direction (e.g., the X-axis direction). In at least one example, the side surfaces of the first barrier layer 130, the recording layer 140, the second barrier layer 150, and the gate electrode layer 160 may conform to the same plane. The first barrier layer 130 may be formed to be in direct contact with the first semiconductor layer included in the substrate 120. The first barrier layer 130 may be a material layer configured to inhibit (or prevent) mobile ions 170 from diffusing or leaking from the recording layer 140 to the channel (e.g., to the first semiconductor layer included in the substrate 120). The first barrier layer 130 may be a single layer or a multi-layer. In at least one example, the first barrier layer 130 may include, but is not limited to, an insulating oxide, a metal oxide nitride, and/or a metal carbide. In at least one example, the insulating oxide may include, but is not limited to, one or more of hafnium oxide (HfO) and/or zirconium oxide (ZrO). The thickness of the first barrier layer 130 may be about 5 nanometer (nm) to about 10 nm, but is not limited thereto.

The recording layer 140 may include mobile ions 170. The recording layer 140 is configured have at least two different states based on the distribution state of the mobile ions 170 within the recording layer 140. Thereby, the recording layer 140 may be referred to as having an adjustable distribution state. The two different states may represent bit data 0 and 1. Therefore, the recording layer 140 including the mobile ions 170 may be expressed as a data recording layer or a data storage layer, and may be configured to as a binary memory (e.g., using the two different states) and/or analog memory (e.g., using states between and including the two different states). The recording layer 140 may also be expressed as a solid electrolyte layer.

Immediately after the first nonvolatile memory device 100 is manufactured, the mobile ions 170 may be evenly distributed throughout the recording layer 140 as illustrated in FIG. 1 in a state when no voltage is applied to the first nonvolatile memory device 100. Even when mobile ions 170 are uniformly distributed throughout the recording layer 140 in this manner, the recording layer 140 may be in one of several states that the recording layer 140 may have. If the mobile ions 170 are uniformly distributed throughout the recording layer 140, the first nonvolatile memory device 100 may have a first threshold voltage V1th. The first threshold voltage V1th may also be referred to as an intrinsic threshold voltage, an initial threshold voltage, or a first threshold voltage. The various states of the first nonvolatile memory device 100 may be states distinguished according to the threshold voltage of the first nonvolatile memory device 100. For example, when the first nonvolatile memory device 100 has a first threshold voltage, the first nonvolatile memory device 100 may be stated to be in a first state. When the first nonvolatile memory device 100 is in a state higher or lower than the first threshold voltage, the first nonvolatile memory device 100 may be stated to be in a second state or a third state. The threshold voltage state of the first memory device 100 may vary depending on the distribution state of the mobile ions 170, as described below.

The mobile ions 170 may be formed by including metal ions in a material to be deposited as a recording layer in a process of forming the recording layer 140. For example, after evenly mixing metal ions of a given concentration into the material to be deposited, the material mixed with the metal ions is deposited on the first barrier layer 130 using a deposition method, and thus, a recording layer 140 including mobile ions 170 that are uniformly distributed may be formed. In at least one example, the deposition method may use an atomic layer deposition (ALD) method, but is not limited thereto.

The mobile ions 170 may include a cation having a mass greater than that of an electron. In at least one example, the mobile ions 170 may include an alkali metal ion and/or an alkali-earth metal ion, but is not limited thereto. In terms of mobility, the alkali metal ions may be faster than the alkali-earth metal ions. The alkali metal may include at least one of lithium (Li), sodium (Na), potassium (K), rubidium (Rb), and/or cesium (Cs), but is not limited thereto. The alkali-earth metal may include at least one of beryllium (Be), magnesium (Mg), calcium (Ca), strontium (Sr), and/or barium (Ba), but is not limited thereto. The mobile ions 170 may have a concentration at a doping level, but may also have a concentration higher than the doping level (e.g., a concentration comparable to an alloy). In at least one example, the concentration of the mobile ions 170 may be about 1×10²² ions/cm³ or greater.

In at least one example, the recording layer 140 may include an insulating material as a solid-state electrolyte. The insulating material may include an oxide or a nitride. For example, the recording layer 140 may include silicon oxide and/or aluminum oxide. In at least example, the recording layer 140 may include an amorphous material layer. The thickness of the recording layer 140 may be about 5 nm to about 10 nm.

In at least one embodiment, the second barrier layer 150 may be provided to cover an entire upper surface of the recording layer 140 and may be in contact with the entire upper surface of the recording layer 140. The second barrier layer 150 may be (and/or include) a material layer configured to inhibit and/or prevent mobile ions 170 of the recording layer 140 from diffusing or leaking to the gate electrode layer 160. The thickness of the second barrier layer 150 may be about 5 nm to about 10 nm, but is not limited thereto. In at least one example embodiment, the material of the second barrier layer 150 may be the same as the material of the first barrier layer 130. However, among materials having the same barrier properties, the first and second barrier layers 130 and 150 may include different materials from each other.

The gate electrode layer 160 may be provided to cover an entire upper surface of the second barrier layer 150 and be in contact with the entire upper surface of the second barrier layer 150 but may also be in contact with only a part of the upper surface of the second barrier layer 150. A voltage applied to the first gate stack GS1 may be applied through the gate electrode layer 160. The gate electrode layer 160 may include a gate material of a transistor or a gate material of a field-effect transistor (FET) type memory device, but is not limited thereto. The gate electrode layer 160 may include, for example, a conductive material such as a zero-bandgap material.

The first barrier layer 130, the recording layer 140, and the second barrier layer 150 positioned between the gate electrode layer 160 and the first semiconductor layer included in the substrate 120 in the first gate stack GS1 may be collectively referred to as a gate insulating layer or as a gate dielectric layer.

The first nonvolatile memory device 100 of FIG. 1 may correspond to a unit memory cell of a memory device, and thus may also be referred to as a first memory cell 100 (that is nonvolatile).

A plurality of first memory cells 100 may be aligned in one or more directions parallel to the substrate 120 (e.g., the first direction or X-axis direction) to form a memory cell array or a memory array. In the memory cell array, the plurality of first memory cells 100 may be formed to share or not share the first barrier layer 130, the recording layer 140, and the second barrier layer 150.

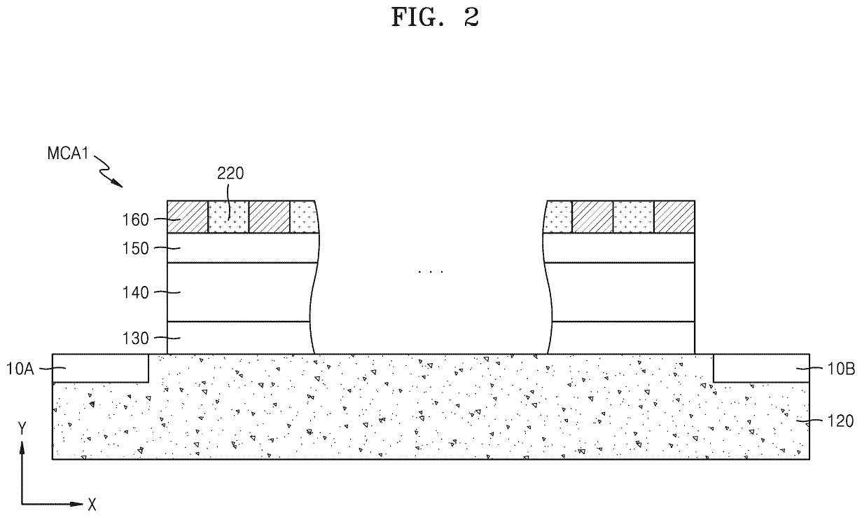

FIG. 2 shows a first memory cell array MCA1 including of a plurality of first memory cells 100. For convenience of illustration, the mobile ions 170 included in the recording layer 140 are not shown in FIG. 2.

Referring to FIG. 2, between a first doped region 10A and a second doped region 10B, a first barrier layer 130, a recording layer 140, and a second barrier layer 150 are sequentially stacked on a first semiconductor layer 120. The first barrier layer 130 is spaced apart from the first and second doped regions 10A and 10B. A plurality of gate electrode layers 160 are aligned at a given interval in the X-axis direction on the second barrier layer 150. An alignment interval of the gate electrode layers 160 may be constant or may be not constant. An insulating layer 220 may be provided between the plurality of gate electrode layers 160. In at least one embodiment, the insulating layer 220 may completely fill the space between the gate electrode layers 160. The insulating layer 220 may be a single layer formed with a single insulating material, or may be a multilayer in which single layers of different insulating materials are stacked. The insulating layer 220 is arranged between the gate electrode layers 160, and thus, may be referred to as a spacer, a gate spacer, or a spacer layer. The insulating layer 220 may include an oxide or a nitride, but is not limited thereto.

Heights of upper surfaces or surfaces exposed to the outside of the gate electrode layer 160 and the insulating layer 220 may be the same. In other words, the upper surface of the gate electrode layer 160 and the upper surface of the insulating layer 220 may conform to the same plane. A width of the insulating layer 220 in the first direction may be the same as or different from a width of the gate electrode layer 160 in the first direction In at least one example, the plurality of first memory cells 100 may be aligned in a second direction that is perpendicular to the first direction, as described below. The second direction may be the Y-axis direction.

In the first memory cell array MCA1, one gate electrode layer 160 and the corresponding second barrier layer 150, the recording layer 140, and the first barrier layer 130 and the first and second doped regions 10A and 10B may correspond to one first memory cell 100.

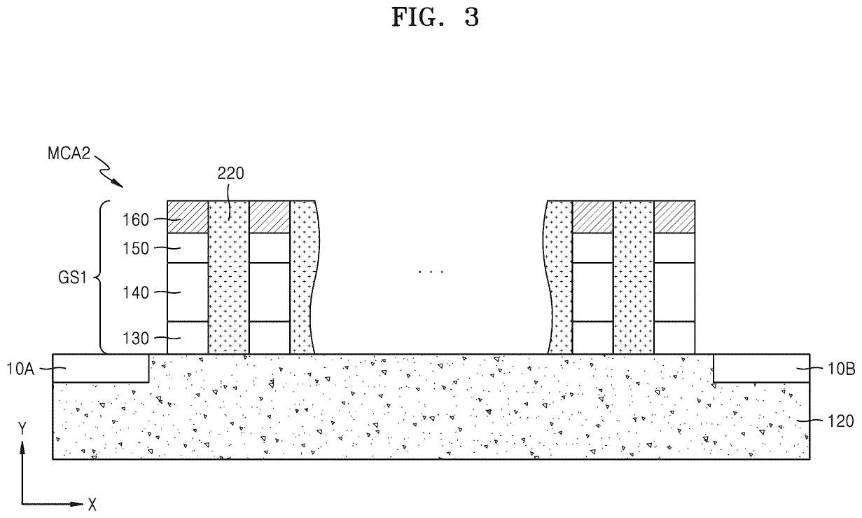

FIG. 3 shows a second memory cell array MCA2 including of the plurality of first memory cells 100. Only the parts that are different from the first memory cell array MCA1 of FIG. 2 will be described. For convenience of illustration, the mobile ions 170 included in the recording layer 140 are not illustrated in FIG. 3.

Referring to FIG. 3, an insulating layer 220 may be provided to contact the first semiconductor layer included in the substrate 120 by penetrating through the first barrier layer 130, the recording layer 140, and the second barrier layer 150. Accordingly, the first barrier layer 130, the recording layer 140, and the second barrier layer 150 of the plurality of first memory cells 100 forming the second memory cell array MCA2 are not shared with each other, and only the first and second doped regions 10A and 10B are shared with each other. In other words, in the case of the second memory cell array MCA2, the plurality of first gate stacks GS1 are arranged independently of each other and are spaced apart from each other on the first semiconductor layer included in the substrate 120.

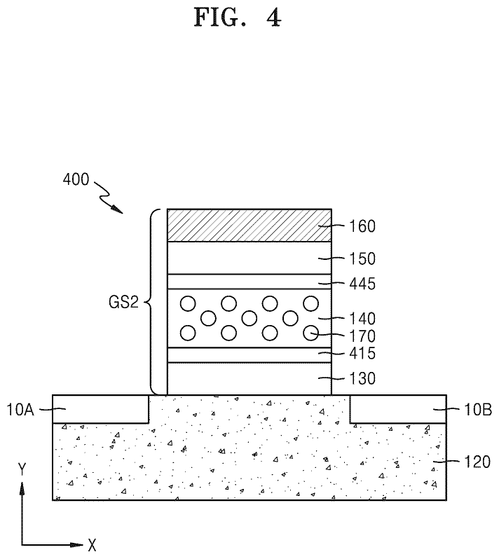

FIG. 4 shows a second nonvolatile memory device 400 according to at least one example embodiment. For purposes of brevity, the parts that are different from the first nonvolatile memory device 100 of FIG. 1 will be mainly described; thereby, repeat descriptions may be omitted. The second nonvolatile memory device 400 may also be referred to as a nonvolatile second memory cell 400.

Referring to FIG. 4, the second nonvolatile memory device 400 includes a second gate stack GS2 having a different configuration from the first gate stack GS1 of FIG. 1.

In the second gate stack GS2, a first auxiliary barrier layer 415 is provided between the first barrier layer 130 and the recording layer 140, and/or a second auxiliary barrier layer 445 is provided between the recording layer 140 and the second barrier layer 150. The first auxiliary barrier layer 415 may include a material layer configured to capture ions passing through the first auxiliary barrier layer 415. Therefore, the first auxiliary barrier layer 415 may also be referred to as an ion capture layer, etc. A thickness of the first auxiliary barrier layer 415 may be about 1 nm to about 3 nm. In at least one example, the first auxiliary barrier layer 415 may include an oxide layer, for example, a silicon oxide layer and/or an aluminum oxide layer. In at least one example, the first auxiliary barrier layer 415 may include an additive in the oxide, and a dopant may be injected into the oxide. In at least one example, the first auxiliary barrier layer 415 may be a material layer including phosphorus (P) or fluorine (F) in the oxide but is not limited thereto. The role, thickness, and material of the second auxiliary barrier layer 445 may be the same as and/or substantially similar to those of the first auxiliary barrier layer 415 but may be different from those of the first auxiliary barrier layer 415 in terms of material and thickness.

The first barrier layer 130, the first auxiliary barrier layer 415, the recording layer 140, the second auxiliary barrier layer 445, and the second barrier layer 150 arranged between the gate electrode layer 160 and the first semiconductor layer included in the substrate 120 in the second gate stack GS2 may be collectively referred to as a gate insulating layer or a gate dielectric layer.

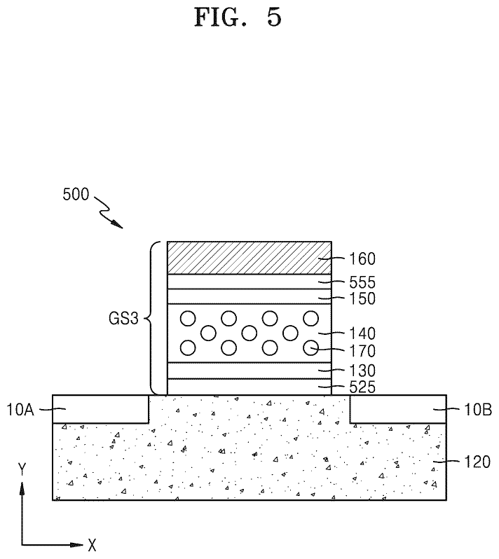

FIG. 5 shows a third nonvolatile memory device 500 according to at least one example embodiment. For purposes of brevity, the parts that are different from the first nonvolatile memory device 100 of FIG. 1 will be mainly described; thereby, repeat descriptions may be omitted. The third nonvolatile memory device 500 may also be referred to as a nonvolatile third memory cell 500.

Referring to FIG. 5, the third nonvolatile memory device 500 includes a third gate stack GS3 having a different configuration from the first gate stack GS1 of FIG. 1 and the second gate stack GS2 of FIG. 2.

In the third gate stack GS3, a third auxiliary barrier layer 525 is provided between the first barrier layer 130 and the first semiconductor layer included in the substrate 120, and a fourth auxiliary barrier layer 555 is provided between the second barrier layer 150 and the gate electrode layer 160.

In at least one example, the third auxiliary barrier layer 525 may be a layer configured to control tunneling of carriers and/or diffusion of ions and may be a material layer configured to control tunneling of carriers and/or diffusion of ions between the first semiconductor layer included in the substrate 120 and the recording layer 140. In at least one example, the third auxiliary barrier layer 525 may include an oxide layer. In at least one example, the oxide layer may include, but is not limited to, aluminum (Al) and fluorine (F). In at least one example, the third auxiliary barrier layer 525 may be formed to a thickness of about 1 nm to about 3 nm.

The fourth auxiliary barrier layer 555 may be a layer configured to control tunneling of carriers or diffusion of ions and may be a material layer configured to control tunneling of carriers or diffusion of ions between the gate electrode layer 160 and the recording layer 140. In at least one example, the material and thickness of the fourth auxiliary barrier layer 555 may be the same as the material and thickness of the third auxiliary barrier layer 525 but may also be different from each other.

The third auxiliary barrier layer 525, the first barrier layer 130, the recording layer 140, the second barrier layer 150, and the fourth auxiliary barrier layer 555 arranged between the gate electrode layer 160 and the first semiconductor layer included in the substrate 120 in the third gate stack GS3 may be collectively referred to as a gate insulating layer or a gate dielectric layer.

The second memory cell 400 of FIG. 4 and the third memory cell 500 of FIG. 5 may also form the memory cell arrays MCA1 and MCA2 as illustrated in FIGS. 2 and 3, like the first memory cell 100.

In at least one example, in the first to third memory cells 100, 400, and 500, the mobile ions 170 of the recording layer 140 may be supplied to the recording layer 140 in a method other than the doping method. For example, in the first to third memory cells 100, 400, and 500, a metal ion rich layer including a large amount of metal ions may be provided between the recording layer 140 and the second barrier layer 150 and the second auxiliary barrier layer 445 directly above the recording layer 140, and ions may be supplied from the metal ion rich layer to the recording layer 140. The metal ion rich layer may be referred to as a metal ion storage layer or a reservoir layer.

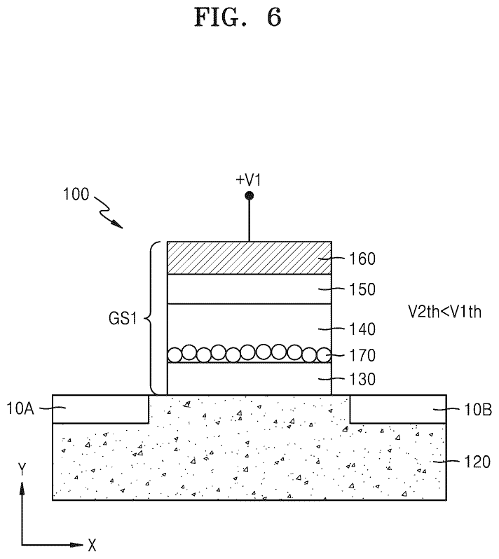

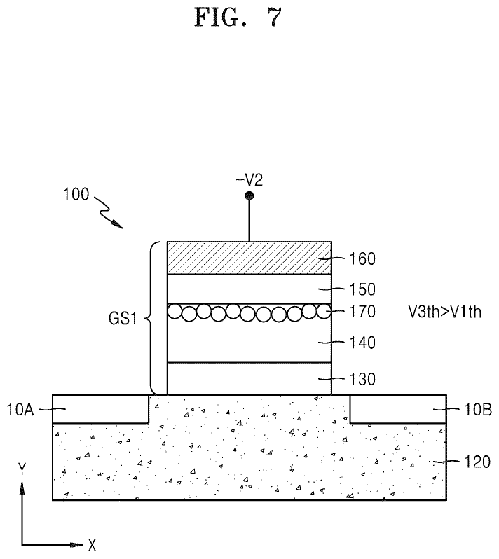

FIGS. 6 and 7 show an operation of a nonvolatile memory device according to at least one example embodiment.

The operation illustrated in FIGS. 6 and 7 is targeted at the first memory cell 100 of FIG. 1, but because the operation principle is related to the redistribution of mobile ions 170 included in the recording layer 140, the operation illustrated in FIGS. 6 and 7 may be equally applied to the operation of the second and third memory cells 400 and 500 including the same (or a substantially similar) recording layer 140.

As illustrated in FIG. 6, when a positive first voltage +V1 is applied to the gate electrode layer 160, the mobile ions 170 of the recording layer 140 move downward within the recording layer 140 and gather near a bottom of the recording layer 140, that is, near an interface between the recording layer 140 and the first barrier layer 130. Accordingly, the distribution state of the mobile ions 170 in the recording layer 140 is different from before the first voltage +V1 is applied so that the density of the mobile ions 170 in a lower layer (a part adjacent to the first barrier layer 130) of the recording layer 140 increases, and the density of the mobile ions 170 may decrease rapidly from the lower layer to the upper layer of the recording layer 140. In at least one example, after the first voltage +V1 is applied to the gate electrode layer 160, the mobile ions 170 may not exist in a detectable range within the remaining area of the recording layer 140 (e.g., may exist only in the lower layer). In at least one example embodiment, as the first voltage +V1 is applied, the ion density of the layer (region) adjacent to the channel in the recording layer 140 may increase and the ion density of the layer (region) adjacent to the gate electrode 160 may decrease. Accordingly, electrons may gather in a region (channel) of the first semiconductor layer included in the substrate 120 located between the first and second doped regions 10A and 10B and directly below the first gate stack GS1. As a result, a threshold voltage of the first memory cell 100 may be lowered to a second threshold voltage V2th lower than the first threshold voltage V1th, which is an intrinsic threshold voltage of the first memory cell 100 (V2th<V1th).

The first memory cell 100 having the second threshold voltage V2th may be regarded as a second state. The second state may correspond to one of the memory states that the first memory cell 100 may have. In at least one example, the first voltage +V1 may correspond to a data write voltage or a program voltage, and the second state may be regarded as a state in which bit data 1 or 0 is written.

Next, in the ion distribution state of the recording layer 140 of FIG. 1, when a negative second voltage −V2 is applied to the gate electrode layer 160 as shown in FIG. 7, the mobile ions 170 of the recording layer 140 move upward within the recording layer 140 and gather near an upper surface of the recording layer 140, that is, near an interface between the recording layer 140 and the second barrier layer 150. Accordingly, the distribution state of the mobile ions 170 in the recording layer 140 may be different from before the second voltage −V2 is applied to the gate electrode layer 160, and thus, the density of the mobile ions 170 in an upper layer (a part adjacent to the second barrier layer 150) of the recording layer 140 may increase, and the density of the mobile ions 170 may decrease rapidly from the upper layer to the lower layer of the recording layer 140. In at least one example, after the second voltage −V2 is applied, mobile ions 170 may not exist in the remaining region of the recording layer 140 except for the upper layer. In other words, as the second voltage −V2 is applied, mobile ions 170 may not exist in a detectable range in the layer (region) adjacent to the channel in the recording layer 140. The ion density may decrease rapidly compared to before the application of the second voltage −V2, and the ion density in the layer (region) farthest from the channel in the recording layer 140 may increase. In at least one example embodiment, as the second voltage −V2 is applied, the ion density of the layer (region) adjacent to the channel in the recording layer 140 may decrease and the ion density of the layer (region) adjacent to the gate electrode 160 may increase. Accordingly, holes are collected in a region (channel) of the first semiconductor layer included in the substrate 120 directly below the first gate stack GS1. As a result, the threshold voltage of the first memory cell 100 may be increased to a third threshold voltage V3th higher than the first threshold voltage V1th of the first memory cell 100 (V3th>V1th).

The first memory cell 100 having the third threshold voltage V3th may be considered to be in a third state different from the first and second states. The third state may correspond to another one of the memory states that the first memory cell 100 may have. In at least one example, the second voltage −V2 may correspond to a data write voltage or a program voltage, and the third state may be regarded as a state in which bit data 1 or 0 is written. In at least one example, the second state may be considered as a state in which bit data ‘1’ is recorded, the third state may be considered as a state in which bit data ‘0’ is recorded, or vice versa.

In at least one example, the first memory cell 100 may have multiple states different from the first to third states. That is, the mobile ions 170 in the recording layer 140 may be distributed in various forms different from the distribution corresponding to the first to third states, and each distribution may represent one memory state. In at least one example, the mobile ions 170 in the recording layer 140 may be distributed in three or more different forms depending on the state of the applied voltage or the magnitude of the voltage. For example, the mobile ions 170 may be distributed in n (n=1, 2, 3, 4 . . . ) different forms. Because the threshold voltage of the first memory cell 100 may vary depending on the distribution state of the mobile ions 170 in the recording layer 140, the fact that the mobile ions 170 may be distributed in n different distribution forms suggests that the first memory cell 100 may have n different threshold voltages, which suggests that the first memory cell 100 may have n different memory states.

As a result, by controlling the state or magnitude of the voltage applied to the first memory cell 100, the first memory cell 100 may store multiple bits. For example, the first memory cell 100 may store two bit data (e.g., 00, 01, 10, or 11), three bit data (000, 001, 010, 011, 100, 101, 110, or 111), or may store four or more bit data.

In at least one example, the absolute value of the first voltage +V1 and the absolute value of the second voltage −V2 may be the same. In at least one example, one of the first voltage +V1 and the second voltage −V2 may be an operating voltage for data recording (programming), and the other may be an operating voltage for erasing the recorded data.

Data recorded in the first memory cell 100 may be read by applying a voltage between the second threshold voltage V2th and the third threshold voltage V3th to the gate electrode layer 160 as a read voltage and measuring a current flowing between the first and second doped regions 10A and 10B.

In at least one example, if the first threshold voltage V1th, which is the intrinsic threshold voltage of the first memory cell 100, is used as one state of the memory state, the read voltage may be a voltage between the first threshold voltage V1th and the second threshold voltage V2th or a voltage between the first threshold voltage V1th and the third threshold voltage V3th.

As described above, the operation of the first memory cell 100 is not to tunnel electrons in the channel, but to control the distribution state of the mobile ions 170 in the recording layer 140, so the high operating voltage required in the charge trap flash (CTF) known so far is not required. Therefore, if the first memory cell 100 is used, a memory operation may be possible even without a high-voltage transistor operating section required in the peripheral circuit of the CTF.

In addition, because the mobile ions 170 have a greater mass than electrons, the mobile ions 170 may be relatively static compared to electrons. That is, the lateral movement of the mobile ions 170 may be slower than that of electrons. Therefore, if the first memory cell 100 is used as a unit memory cell of a memory device (e.g., VNAND) including a vertical cell string structure, recorded data may be kept for a relatively longer time without damage or distortion. That is, in the case of a memory device including the first memory cell 100, the retention characteristic may be increased.

In addition, the operating speed of the first memory cell 100 may be affected by the material of the recording layer 140 and the type of mobile ion 170. Therefore, by appropriately selecting the material of the recording layer 140, appropriately selecting the type of the mobile ion 170, or variously combining the material of the recording layer 140 and the type of the mobile ion 170, the operating speed of the first memory cell 100 may be increased and the balance between the operating speed and the retention characteristic may be adjusted.

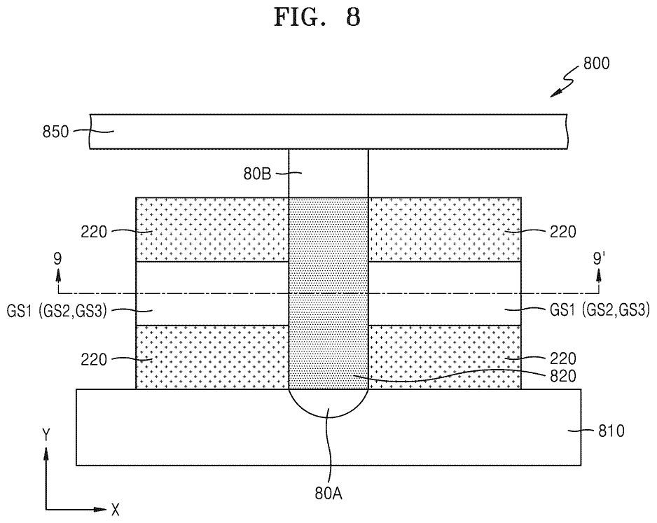

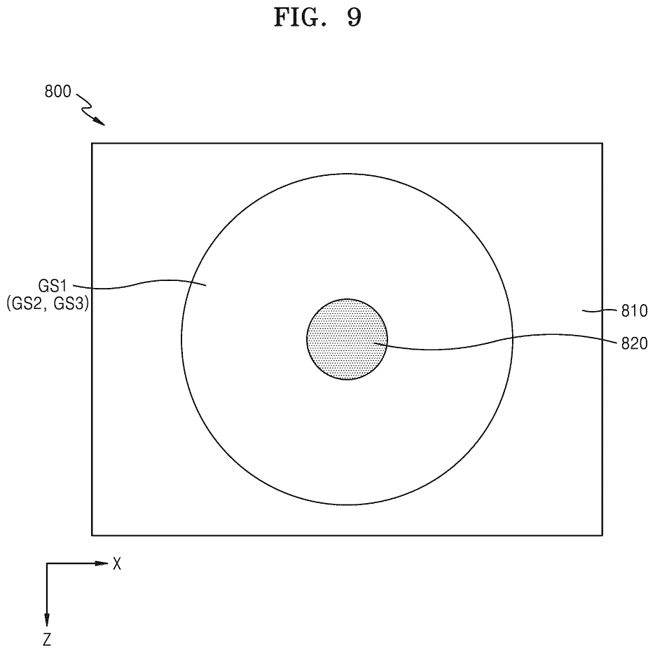

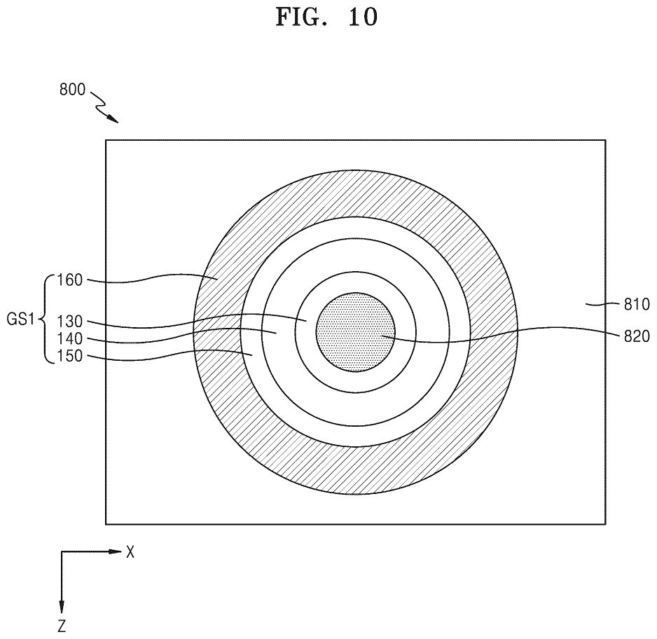

FIG. 8 shows a fourth nonvolatile memory device 800 according to at least one example embodiment, and FIG. 9 is a plan view taken along line 9-9′ of FIG. 8.

The fourth nonvolatile memory device 800 may also be referred to as a fourth memory cell 800. Unlike the first to third memory cells 100, 400, and 500, the fourth memory cell 800 may be referred to as a vertical memory cell in that the semiconductor layer on which a gate stack is formed is vertically formed, and the gate stack is provided in a lateral direction of the semiconductor layer formed vertically.

Referring to FIGS. 8 and 9 together, a third doped region 80A is formed in a region of a substrate 810. The third doped region 80A may be formed by doping a p-type or n-type conductive impurity in the portion of the substrate 810 but is not limited thereto. The third doped region 80A may include a portion of the upper surface of the substrate 810. The substrate 810 may be (or include) a semiconductor substrate including, e.g., an elemental semiconductor (e.g., Si) and/or a compound semiconductor layer and/or may include a semiconductor substrate including the semiconductor. The semiconductor layer in the substrate 810 may be referred as a second semiconductor layer in order to differentiate the second semiconductor layer from the first semiconductor layer in the substrate 120 of FIG. 1 In at least one example, the material of the second semiconductor layer in the substrate 810 may or may not be the same as the first semiconductor layer in the substrate 120 of FIG. 1.

A third semiconductor layer 820 is provided on the third doped region 80A. The third semiconductor layer 820 may be in contact with the third doped region 80A, and in at least one embodiment, an entire bottom surface of the third semiconductor layer 820 may be within the third doped region 80A. A height of the third semiconductor layer 820 in the direction perpendicular to an upper surface of the substrate 810 or in the second direction (e.g., the Y-axis direction) may be greater than a width of the third semiconductor layer 820 in the first direction (e.g., the X-axis direction). The material of the third semiconductor layer 820 may be the same as and/or substantially similar to the material of the first semiconductor layer included in the substrate 120 of FIG. 1 and/or to the material of the second semiconductor layer; but may also be different. In at least one example, as illustrated in FIG. 9, the third semiconductor layer 820 has a vertical insulating layer cylinder (dashed line) at its center, and the third semiconductor layer 820 is provided to surround the insulating layer and may be provided on a side surface of the insulating layer. In this case, the third semiconductor layer 820 may entirely be used as a channel.

An insulating layer 220, a first gate stack GS1, and an insulating layer 220 are sequentially stacked on the substrate 810 surrounding the third semiconductor layer 820.

The insulating layer 220, the first gate stack GS1 (see FIG. 1) and the insulating layer 220 may be provided to completely surround the third semiconductor layer 820 and may be provided to cover an entire side surface of the third semiconductor layer 820 and to be in contact with the entire side surface of the third semiconductor layer 820. The insulating layer 220 provided under the first gate stack GS1 may be expressed as a lower insulating layer, and the insulating layer 220 provided on the first gate stack GS1 may be expressed as an upper insulating layer. Instead of the first gate stack GS1, the second gate stack GS2 (see FIG. 4) or the third gate stack GS3 (see FIG. 5) may be provided. The first gate stack GS1 may be formed in a lateral direction (outward direction perpendicular to the lateral direction) on the side surface of the third semiconductor layer 820. That is, the first barrier layer 130, the recording layer 140, the second barrier layer 150, and the gate electrode layer 160 constituting the first gate stack GS1 may be sequentially stacked in the lateral direction on the side surface of the third semiconductor layer 820. The first gate stack GS1 is spaced apart from the substrate 810.

Geometric shapes of the insulating layer 220, the first gate stack GS1, and the third semiconductor layer 820 on a plane may be a circular shape but may also be a non-circular shape.

A height of an upper surface of the third semiconductor layer 820 and a height of an upper surface of the upper insulating layer 220 may or may not be the same or substantially the same. In at least one example, the upper surface of the third semiconductor layer 820 and the upper surface of the upper insulating layer 220 may form the same plane. A fourth doped region 80B is provided on the upper surface of the third semiconductor layer 820. In at least one example, the fourth doped region 80B may be a region into which the same dopant as the third doped region 80A is injected.

In at least one example, the third doped region 80A may be a source region, and the fourth doped region 80B may be a drain region. In at least one example, the fourth doped region 80B may include a silicon material into which a p-type or n-type dopant is injected.

A bit line 850 is connected to the fourth doped region 80B. The fourth doped region 80B and the bit line 850 may be directly connected to each other but may also be connected to each other through contact plugs. The bit line 850 extends in both directions while being separated from the third semiconductor layer 820 and the upper insulating layer 220.

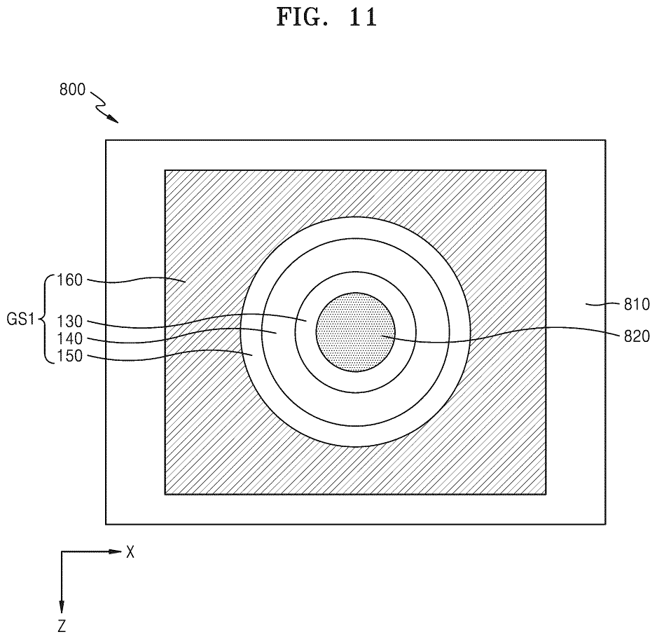

FIG. 10 specifically shows a layer structure of the first gate stack GS1 in FIG. 9.

Referring to FIG. 10, the layers 130, 140, 150, and 160 forming the third semiconductor layer 820 and the first gate stack GS1 may all be concentric circles.

However, as illustrated in FIG. 11, the gate electrode layer 160 of the first gate stack GS1 may not be concentric circles. For example, a planar shape of the gate electrode layer 160 may be a square, but may not be limited to the square shape.

The fourth memory cell 800 may correspond to a unit memory cell of a VNAND. Therefore, a VNAND having a recording layer and a channel formed vertically by a plurality of fourth memory cells 800 may be formed.

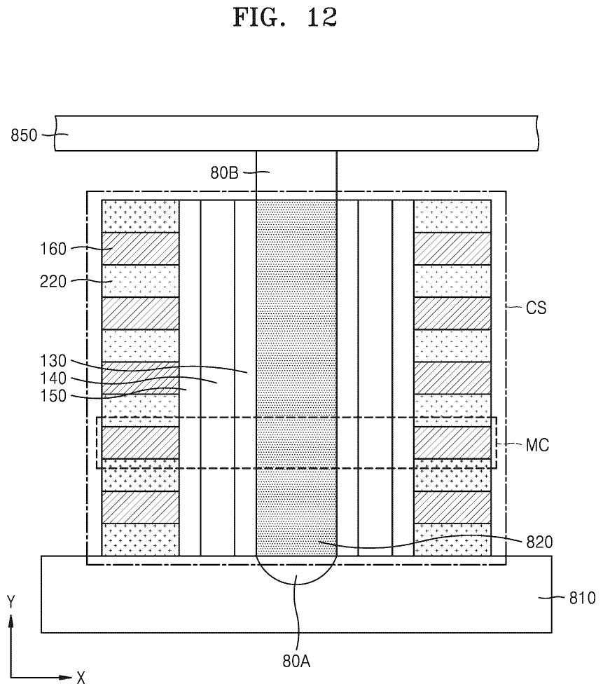

FIG. 12 illustrates an example of the VNAND, in which five-unit memory cells MC are sequentially stacked on one surface (e.g., X-Z plane) of the substrate 810 in a direction perpendicular to the one surface (e.g., Y-axis direction) of the substrate 810. The unit memory cell MC may be the remaining portion of the fourth memory cell 800 excluding the substrate 810, the fourth doped region 80B, and the bit line 850. Therefore, the unit memory cell MC may be viewed as being the same as (or substantially similar to) the fourth memory cell 800. The number of unit memory cells MC sequentially stacked in the vertical direction may be N. A plurality of unit memory cells MC sequentially stacked in the vertical direction on the substrate 810 may form a cell string CS in the VNAND.

The gate electrodes 160 of each memory cell MC vertically stacked in the cell string CS may be electrically separated by the insulating layer 220. In addition, a channel (a layer adjacent to the first barrier layer 130 in the third semiconductor layer 820), the first and second barrier layers 130 and 150 and the recording layer 140 of each memory cell MC in the cell string CS may be connected to each other in the vertical direction.

In the cell string CS, a lower end of the third semiconductor layer 820 is in contact with the third doped region 80A of the substrate 810, and the upper end of the third semiconductor layer 820 is connected to the bit line 850 through the fourth doped region (layer) 80B. The third doped region 80A may be a common source region shared by other cell strings. A bottom of the cell string CS may be considered as a bottom surface of the cell string CS. The fourth doped region 80B may be provided so as to be in contact with a top surface, that is, the upper surface, of the third semiconductor layer 820 at the top of the cell string CS. The bit line 850 may be located on the fourth doped region 80B and may be in direct contact with the fourth doped region 80B. The fourth doped region 80B is provided between the bit line 850 and the cell string CS. The top of the cell string CS may be considered as an upper surface of the cell string CS.

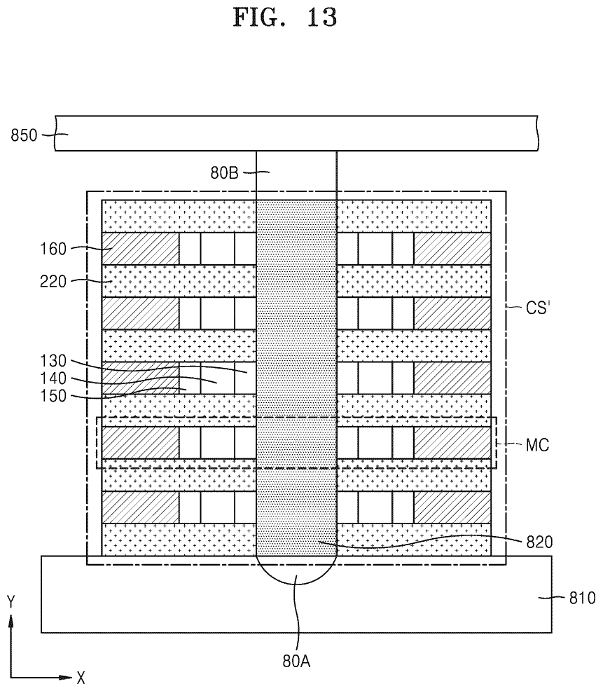

FIG. 13 illustrates a cell string CS′ having a different configuration from the cell string CS of FIG. 12.

In the case of the cell string CS′ illustrated in FIG. 13, not only the gate electrode 160 of each vertically stacked memory cell MC but also the first and second barrier layers 130 and 150 and the recording layer 140 of each memory cell MC may be electrically separated by the insulating layer 220. That is, in the cell string CS′, vertically stacked memory cells MC, the remaining portion except for the channel, are separated by the insulating layer 220. The remaining configuration of FIG. 13 may be the same as FIG. 12.

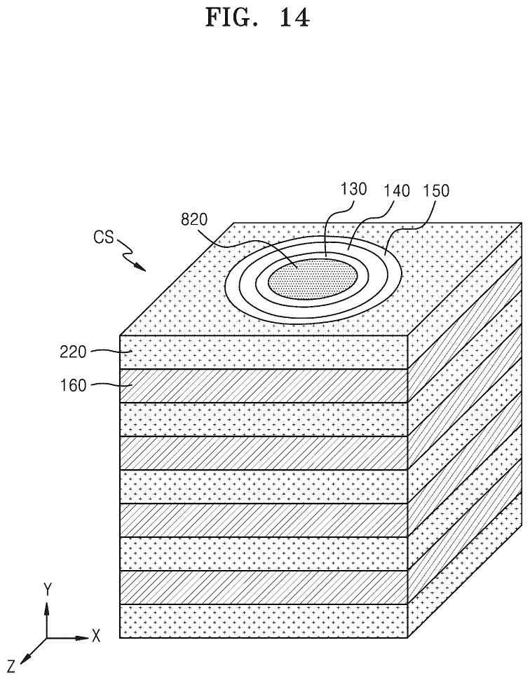

FIG. 14 shows the cell string CS of FIG. 12 in three dimensions.

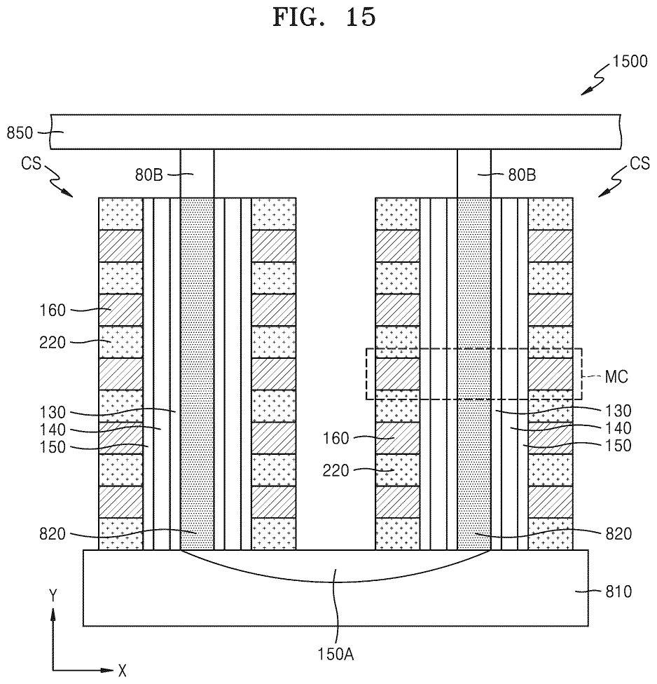

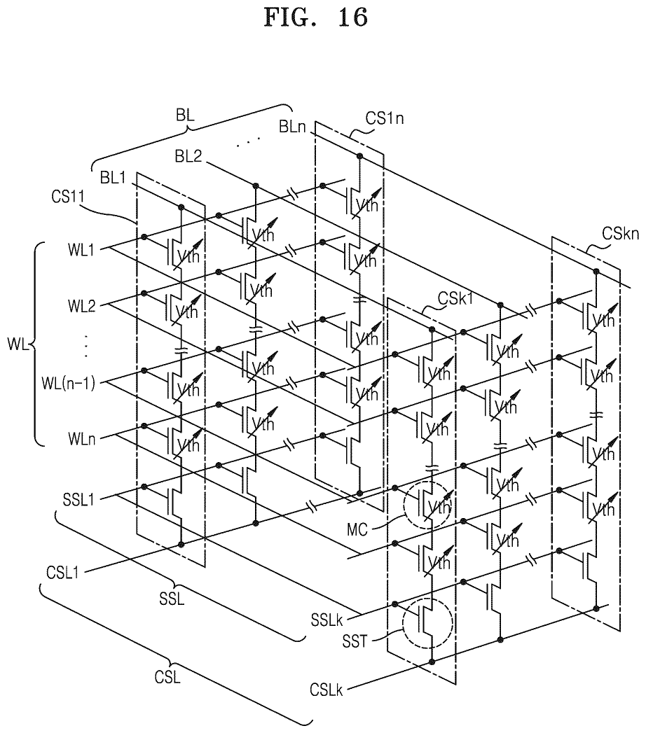

The cell string CS illustrated in FIG. 12 may be provided in multiple numbers on the substrate 810, and FIG. 15 schematically shows a fifth memory device 1500 in which two cell strings CS are provided on the substrate 810 as an example. In at least one example, the fifth memory device 1500 may be a VNAND.

FIG. 16 is an equivalent circuit diagram for the fifth memory device 1500 of FIG. 15. In FIG. 16, the overlapping mark of Vth and arrows indicate that the corresponding memory cell MC is a variable threshold voltage memory cell.

Referring to FIG. 15 and FIG. 16 together, the detailed configuration of the fifth memory device 1500 is as follows.

A plurality of cell strings CS are provided on the substrate 810.

The second semiconductor layer in the substrate 810 may include a silicon material doped with a first-type impurity. For example, the substrate 810 may include a silicon material doped with a p-type impurity. For example, the second semiconductor layer in substrate 810 may be a p-type well (e.g., a pocket p well). Hereinafter, it is assumed that the second semiconductor layer in substrate 810 is a silicon layer doped with a p-type impurity. However, the substrate 810 is not limited to a p-type silicon layer.

A fifth doped region 150A, which is a source region, is provided on the second semiconductor layer in the substrate 810. The fifth doped region 150A may be a region doped with the same dopant as the third doped region 80A. The fifth doped region 150A may be an n-type doped region different from the substrate 810. Hereinafter, the fifth doped region 150A is assumed to be a region doped with an n-type dopant. However, the fifth doped region 150A is not limited to n-type. The fifth doped region 150A may be connected to a common source line CSL.

As shown in the circuit diagram of FIG. 16, the cell string CS may be arranged in a matrix form with k*n cells, and may be named CSij (1≤i≤k, 1≤j≤n) according to each row and column position. Each cell string CSij is connected to a bit line BL, a string select line SSL, a word line WL, and a common source line CSL.

Each cell string CSij includes memory cells MC and a string select transistor SST. The memory cells MC and the string select transistor SST of each cell string CSij may be stacked in a height direction.

The rows of a plurality of cell strings CS are respectively connected to different string select lines SSL1 to SSLk. For example, the string select transistors SSTs of the cell strings CS11 to CS1n are commonly connected to the string select line SSL1. The string select transistors SSTs of the cell strings CSk1 to CSkn are commonly connected to the string select line SSLk.

The rows of the multiple cell strings CS are respectively connected to different bit lines BL1 to BLn. For example, the memory cells MC and string select transistors SST of the cell strings CS11 to CSk1 may be commonly connected to the bit line BL1, and the memory cells MC and string select transistors SST of the cell strings CS1n to CSkn may be commonly connected to the bit line BLn.

The rows of the multiple cell strings CS may respectively be connected to different common source lines CSL1 to CSLk. For example, the string select transistors SST of the cell strings CS11 to CS1n may be commonly connected to a common source line CSL1, and the string select transistors SST of the cell strings CSk1 to CSkn may be commonly connected to a common source line CSLk.

The gate electrodes of the memory cells MC located at the same height from the substrate 810 or the string select transistors SST are commonly connected to one word line WL, and the gate electrodes of the memory cells MC located at different heights may be connected to different word lines WL1 to WLm, respectively.

The illustrated circuit structure is an example. For example, the number of rows of the cell strings CS may increase or decrease. As the number of rows of the cell strings CS changes, the number of string select lines connected to the rows of the cell strings CS and the number of cell strings CS connected to one bit line may also change. As the number of rows of the cell strings CS changes, the number of common source lines connected to the rows of the cell strings CS may also change.

The number of columns of the cell strings CS may also be increased or decreased relative to the number illustrated. As the number of columns of the cell strings CS is changed, the number of bit lines connected to the columns of the cell strings CS and the number of cell strings CS connected to one string selection line may also be changed.

A height of the cell strings CS may also be increased or decreased. For example, the number of memory cells MC stacked in each cell string CS may be increased or decreased. As the number of memory cells MC stacked in each cell string CS is changed, the number of word lines WL may also be changed. For example, the number of string selection transistors provided in each of the cell strings CS may be increased. As the number of string selection transistors provided in each of the cell strings CS is changed, the number of string selection lines or common source lines may also be changed. As the number of string select transistors increases, the string select transistors may be stacked in the same form as the memory cells MC.

For example, writing and reading may be performed in units of rows of cell strings CS. The cell strings CS may be selected in units of rows by the common source line CSL, and the cell strings CS may be selected in units of rows by the string select lines SSL. In addition, a voltage may be applied to the common source lines CSL by forming at least two common source lines as a single unit. A voltage may be applied to the common source lines CSL by forming the entire common source lines CSL as a single unit.

In the selected row of the cell strings CS, writing and reading may be performed in units of pages. A page may be one row of memory cells connected to one word line WL. In a selected row of cell strings CS, memory cells may be selected as a unit of a page by the word lines WL.

As illustrated in FIGS. 12, 14, and 15, the cell string CS may have a form in which a first structure including the third semiconductor layer 820, the first barrier layer 130, the recording layer 140, and the second barrier layer 150 is alternately surrounded by the plurality of gate electrodes 160 and the plurality of insulating layers 220. The insulating layer 220 may be a separation layer that prevents mutual contact of the gate electrodes 160 between vertically stacked gate electrodes 160.

In at least one example, the cell string CS may be replaced with the cell string CS′ illustrated in FIG. 13.

In FIG. 14, the cell string CS is depicted in the shape of a square pillar, but this is an example and the examples not limited thereto. The cell string CS may be formed, for example, in a cylindrical shape.

The shape of the first structure including the third semiconductor layer 820, the first barrier layer 130, the recording layer 140, and the second barrier layer 150 will be described.

For example, referring to FIG. 12 and FIG. 15, the third semiconductor layer 820 has a cylindrical shape in which a length direction is in the Y-axis direction, and the first barrier layer 130, the recording layer 140, and the second barrier layer 150 are sequentially stacked in a radial direction on a flat surface of the cylinder.

The plurality of gate electrodes 160 and the plurality of insulating layers 220 surround an outer surface of the first structure. That is, the plurality of gate electrodes 160 and the plurality of insulating layers 220 are provided on an outer surface of the second barrier layer 150 and are arranged to surround the outer surface of the second barrier layer 150. The plurality of insulating layers 220 are for separating the plurality of gate electrodes 160, and the plurality of gate electrodes 160 and the plurality of insulating layers 220 may be repeatedly stacked while crossing each other in a direction perpendicular to the substrate 810 (Y-axis direction).

The gate electrodes 160 may include a conductive (e.g., a metal) material and/or a highly doped silicon material. Each gate electrode 160 is connected to one of the word lines WL and the string select line SSL. The insulating layer 220 may include various insulating materials such as silicon oxide and silicon nitride.

The manufacturing process of the cell string CS described above may be performed in the order of the internal structure to the external structure. That is, after the first barrier layer 130, the recording layer 140, the second barrier layer 150, and the third semiconductor layer 820 are sequentially deposited as an internal structure, the gate electrode 160 and the insulating layer 220 that have a cylindrical shell shape with the same outer diameter and inner diameter are alternately stacked around the internal structure. The deposition of the above material layers will be described later in the description of the manufacturing method.

One end (bottom) of the third semiconductor layer 820 may be in contact with the fifth doped region 150A, i.e., the common source region. The fourth doped region 80B may be provided at the other end (top) of the third semiconductor layer 820. The recording layer 140 is spaced apart from the fourth doped region 80B. The fourth doped region 80B may include a silicon material doped with the second type. For example, the fourth doped region 80B may include a silicon material doped with an n-type. A bit line 850 may be provided on the fourth doped region 80B. The fourth doped region 80B and the bit line 850 may be directly connected or may be connected through contact plugs.

Each gate electrode 160 and the second barrier layer 150, the recording layer 140, the first barrier layer 130 and the channel facing the gate electrode 160 may form a memory cell MC. The memory cells MC are arranged continuously in the vertical direction (Y-axis direction) to form a cell string CS. As shown in the circuit diagram of FIG. 16, both ends of the cell string CS may be connected to the common source line CSL and the bit line BL. By applying an operating voltage to the common source line CSL and the bit line BL, various operations, such as program (write), read, and erase (delete) operations, may be performed on the plurality of memory cells MC.

For example, if a memory cell MC to be recorded is selected, in the selected cell, a voltage applied to the gate electrode is adjusted so that the threshold voltage becomes the second or third threshold voltage V2th or V3th by moving mobile ions 170, and in the unselected cells, the distribution state of the mobile ions 170 is maintained as it is. Accordingly, desired bit data 1 or 0 may be written to the selected memory cell MC.

In a read operation, a read voltage of a size that does not affect the data state written to the selected memory cell MC is applied, and the cell state (1 or 0) of the selected memory cell MC may be confirmed by measuring a current flowing to the corresponding cell MC by the read voltage between the common source line CSL and the bit line BL. The current measurement may include measuring the presence or absence of current.

In the case of the existing resistive VNAND structure, there is a limit to increasing the number of gate electrodes 160 included in the cell string CS due to the packaging limit according to a height of the cell string CS. In particular, there is a limit to reducing a distance between adjacent gate electrodes 160 due to interference between adjacent memory cells. Accordingly, the memory capacity is limited by a limit value that may reduce the sum of lengths of adjacent gate electrode 160 and insulating layer 220 in the vertical direction (Y-axis direction).

However, the illustrated VNAND structure, unlike the existing resistive VNAND, utilizes a threshold voltage shift of a memory cell through the change in the distribution state of mobile ions 170, and thus, may be free from interference between memory cells than the existing resistive VNAND. Therefore, in the case of the illustrated VNAND, the distance between the gate electrodes 160 may be reduced compared to the existing resistive VNAND, so the integration density may be increased, and the memory capacity may also be increased.

Next, a method of manufacturing the nonvolatile memory device described above will be described with the accompanying drawings.

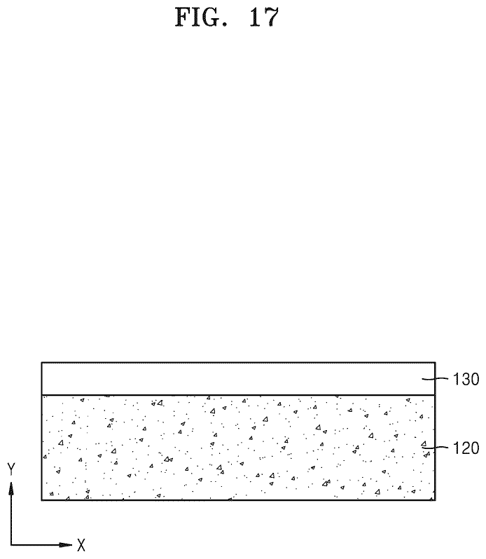

FIGS. 17 to 21 show a first manufacturing method of a nonvolatile memory device step by step, according to an embodiment. The first manufacturing method is a manufacturing method for a unit memory cell, and may be a manufacturing method for the first to third memory devices 100, 400, and 500.

In the following description, the same reference numbers as those mentioned above represent the same members, and the repeat description thereof may be omitted.

First, as shown in FIG. 17, a first barrier layer 130 is formed on a substrate 120. In at least one example, an auxiliary barrier layer corresponding to the third auxiliary barrier layer 525 may be further formed between the substrate 120 and the first barrier layer 130.

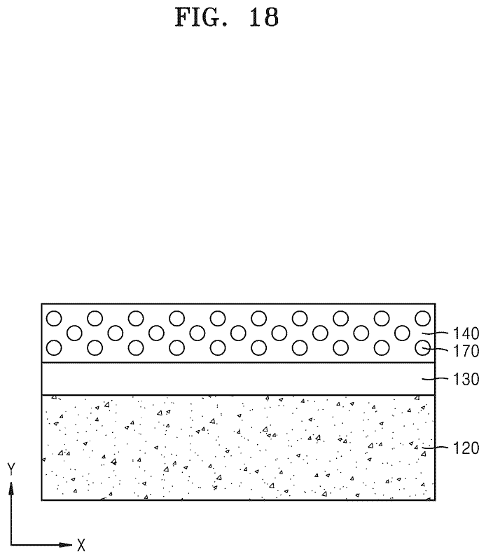

Next, as shown in FIG. 18, a recording layer 140 including mobile ions 170 is formed on the first barrier layer 130. The recording layer 140 may be formed using an ALD method, and/or other deposition methods may also be used. In at least one example, the recording layer 140 including the mobile ions 170 may be deposited on the first barrier layer 130 by a method of supplying a material mixed metal ions to be used as the mobile ions 170 with an insulating material used as the recording layer 140 onto the first barrier layer 130 using ALD. As the recording layer 140 is formed in this way, the mobile ions 170 may be evenly distributed throughout the recording layer 140.

In at least one example, an auxiliary barrier layer corresponding to a first auxiliary barrier layer 415 may be further formed between the first barrier layer 130 and the recording layer 140.

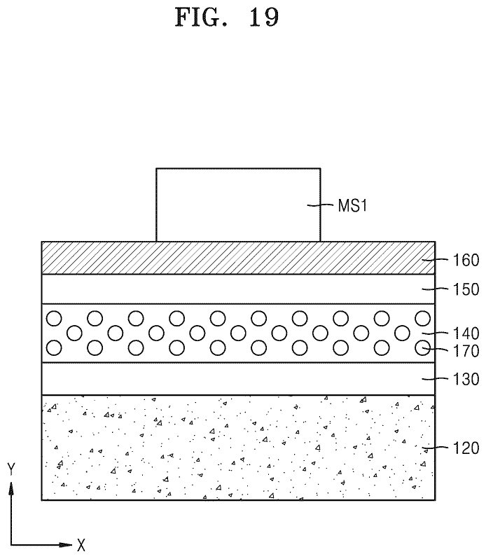

Next, as shown in FIG. 19, a second barrier layer 150 and a gate electrode 160 are sequentially deposited on the recording layer 140. In at least one example, an auxiliary barrier layer corresponding to a second auxiliary barrier layer 445 may be further formed between the recording layer 140 and the second barrier layer 150. In at least one example, an auxiliary barrier layer corresponding to a fourth auxiliary barrier layer 555 may be further formed between the second barrier layer 150 and the gate electrode 160.

In addition, a metal ion-rich layer may be formed between the recording layer 140 and the second barrier layer 150. In this case, the recording layer 140 may be formed in a state in which the recording layer 140 does not include a metal ion material in the formation operation, and the mobile ions 170 of the recording layer 140 may be supplied from the metal ion-rich layer.

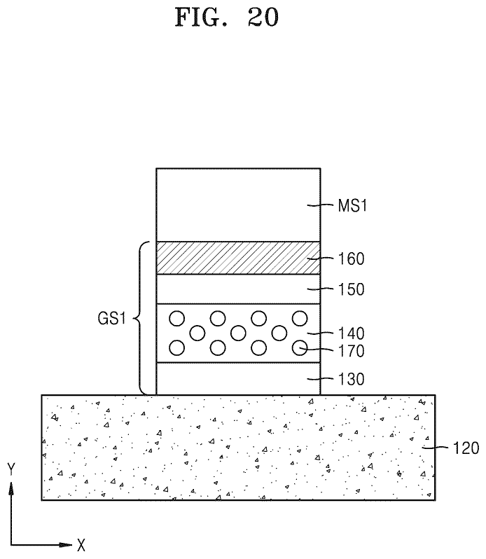

Next, a mask layer MS1 that defines a region corresponding to the first gate stack GS1 is formed on the gate electrode 160. Then, as illustrated in FIG. 20, the gate electrode 160, the second barrier layer 150, the recording layer 140, and the first barrier layer 130 around the mask layer MS1 are etched. The etching is performed until the substrate 120 is exposed. In this way, the first gate stack GS1 is formed on the substrate 120. In the case when the auxiliary barrier layer described above is formed together, the first gate stack GS1 may be the second gate stack GS2 or the third gate stack GS3 or may be a gate stack including all the auxiliary barrier layers described above. After the etching described above, the mask layer MS1 is removed.

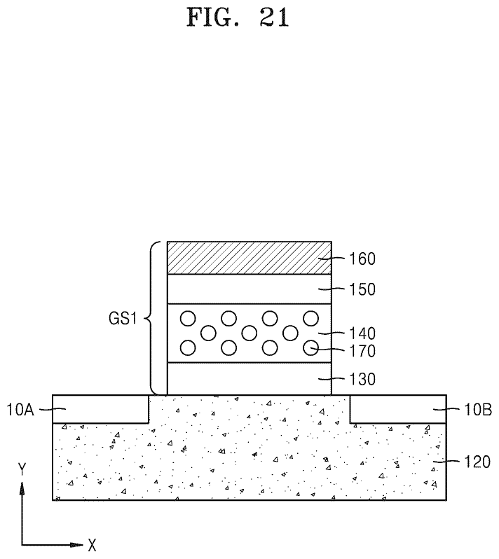

After removing the mask layer MS1, as illustrated in FIG. 21, first and second doped regions 10A and 10B are formed on the substrate 120. The first and second doped regions 10A and 10B may be formed by ion implantation, but are not limited thereto. When the first and second doped regions 10A and 10B are formed, the first gate stack GS1 may be protected by a mask. In at least one example, the first and second doped regions 10A and 10B may be formed while the mask layer MS1 is present.

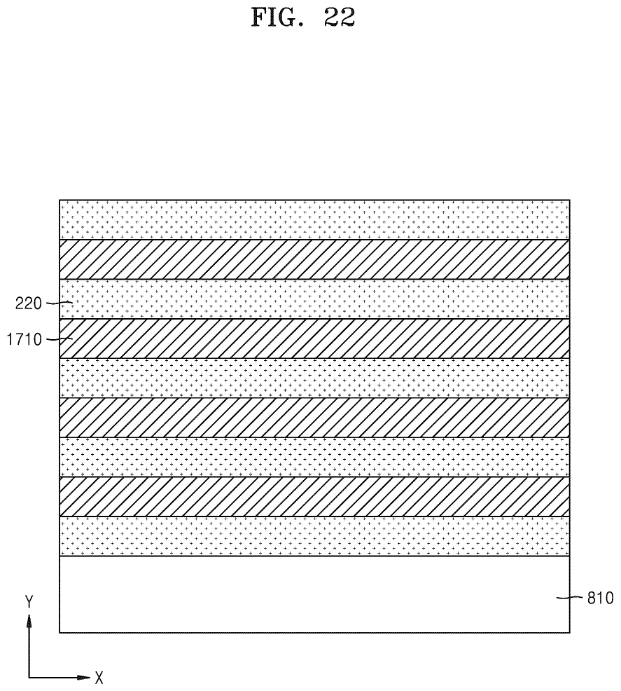

FIGS. 22 to 30B show a second manufacturing method of a nonvolatile memory device step by step, according to at least one example embodiment. In FIGS. 22 to 30B, the drawing marked with A is a cross-sectional view of the drawing marked with B, and the drawing marked with B is a plan view of the drawing marked with A. FIGS. 22 to 30B may be a manufacturing method for the V-NAND illustrated in FIG. 12.

First, referring to FIG. 22, a stack structure is formed, in which an insulating layer 220 and a sacrificial layer 1710 are alternately and repeatedly stacked on a substrate 810. In at least one example, the substrate 810 may be a silicon substrate, for example, a silicon substrate doped with a predetermined impurity. The substrate 810 may be a p-type silicon substrate, but is not limited thereto.

The insulating layer 220 may include an insulating material, for example, may include SiO₂. The sacrificial layer 1710 is a layer for forming a recess structure for forming a channel layer and a recording material layer of a curved path and includes a material having a different etching ratio from the material of the insulating layer 220. The insulating layer 220 may include, for example, SiNx. A thickness of the insulating layer 220 and a thickness of the sacrificial layer 1710 may be determined according to the detailed structure of the memory device to be manufactured. The thickness of the insulating layer 220 and the thickness of the sacrificial layer 1710 may correspond to a gap between the gate electrodes and a length of the gate electrode of the memory device to be manufactured, respectively. In at least one example, the thickness of the sacrificial layer 1710 may be in a range of about 5 nm to about 30 nm, but is not limited thereto. In at least one example, the thickness of the insulating layer 220 may be formed in a range of about 5 nm to about 30 nm, but is not limited thereto. A gate electrode may be formed at the location of the sacrificial layer 1710, and the number of sacrificial layers 1710 may correspond to the number of unit cells of the memory device to be manufactured.

To form the insulating layer 220 and the sacrificial layer 1710, deposition methods such as ALD, metal organic atomic layer deposition (MOALD), chemical vapor deposition (CVD), metal organic chemical vapor deposition (MOCVD), physical vapor deposition (PVD), and/or the like may be used. The above methods may include a process of positioning the substrate 810 in a chamber, heating the chamber to a predetermined temperature, and supplying a source, and the process conditions of temperature and time are adjusted according to the desired thickness.

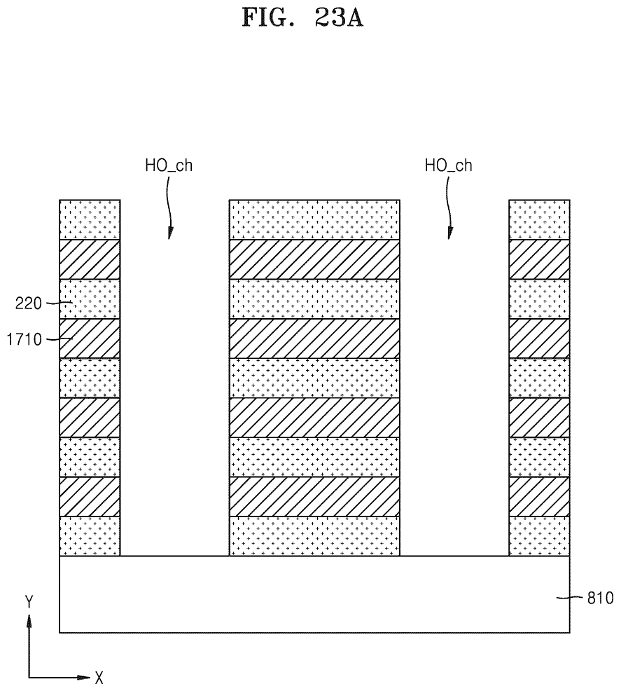

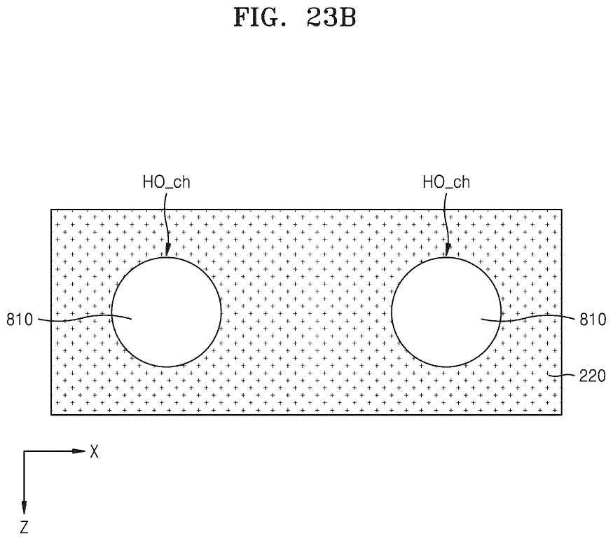

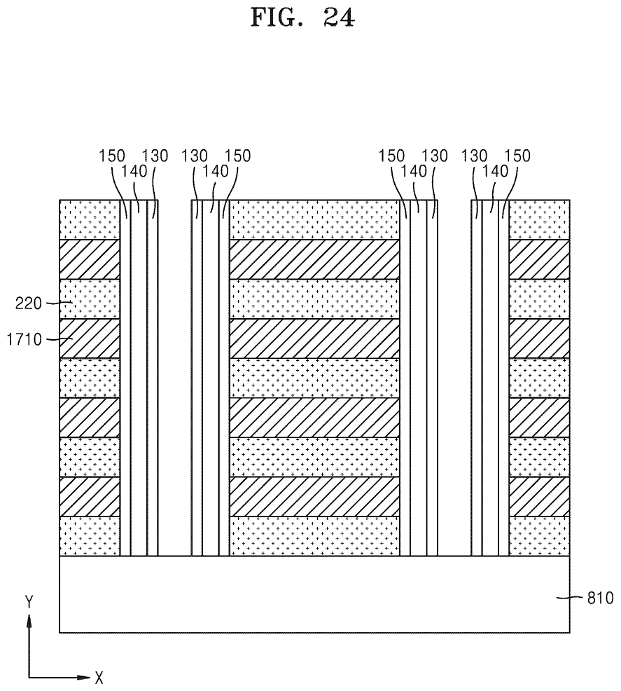

Next, as illustrated in FIGS. 23A and 23B, a channel hole HO_ch is formed in the stack structure of FIG. 22. The channel hole HO_ch is a hole for applying or forming a barrier layer material, a recording material, a channel material, etc. To form the channel hole HO_ch, photolithography and etching processes may be used. The number of channel holes HO_ch is illustrated as two, but this is an example. For example, the number of channel holes HO_ch may be formed as many as the number of cell strings CS described with reference to FIGS. 12 to 16.

Next, as illustrated in FIG. 24, on an inner surface of the channel hole HO_ch, the second barrier layer 150, the recording layer 140, and the first barrier layer 130 are sequentially formed in a direction toward the center of the channel hole HO_ch in a direction in which a radius of the channel hole HO_ch becomes smaller. For convenience of illustration, mobile ions included in the recording layer 140 are not illustrated.

For the formation of the material layers 130, 140, and 150, a deposition method such as ALD, MOALD, CVD, MOCVD, PVD, or Plasma Enhanced ALD (PEALD) may be used. The above methods may include a process of positioning a stack structure in which the channel hole HO_ch is formed in a chamber, heating the chamber to a predetermined temperature, and supplying a source, and the process conditions of temperature and time may be adjusted according to the desired thickness of each layer.

In at least one example, an auxiliary barrier layer corresponding to the fourth auxiliary barrier layer 555 may be further formed between the inner surface of the channel hole HO_ch and the second barrier layer 150.

In at least one example, an auxiliary barrier layer corresponding to the second auxiliary barrier layer 445 may be further formed between the second barrier layer 150 and the recording layer 140.

In at least one example, an auxiliary barrier layer corresponding to the first auxiliary barrier layer 415 may be further formed between the first barrier layer 130 and the recording layer 140.

In at least one example, a metal ion-rich layer may be formed between the recording layer 140 and the second barrier layer 150. In this case, the mobile ions 170 of the recording layer 140 may not be supplied in the operation of forming the recording layer 140, but may be supplied from the metal ion-rich layer after the recording layer 140 is formed.

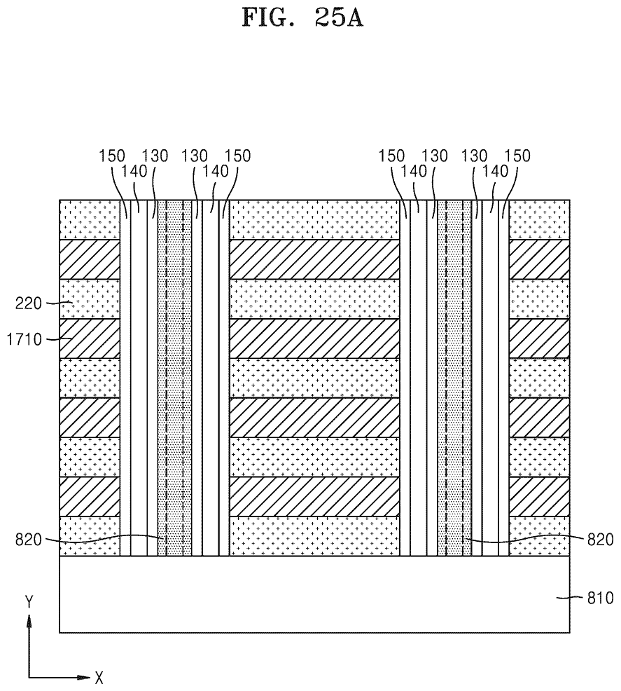

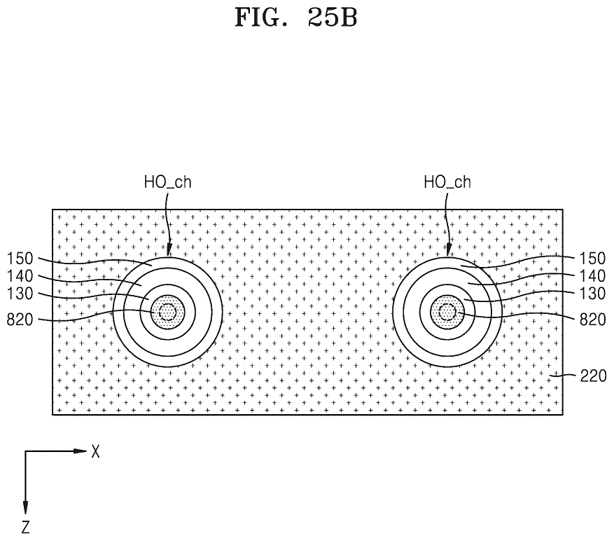

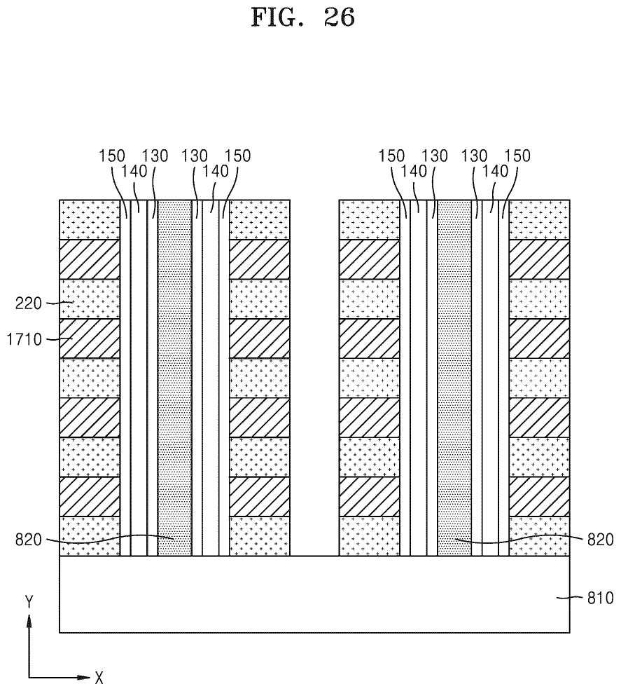

Next, as shown in FIG. 25A and FIG. 25B, a third semiconductor layer 820 is formed in a remaining space inside the channel hole HO_ch. The remaining space inside the channel hole HO_ch may be completely filled with the third semiconductor layer 820. In at least one example, an auxiliary barrier layer corresponding to a third auxiliary barrier layer 525 may be further formed between the third semiconductor layer 820 and the first barrier layer 130.

In at least one example, instead of filling the remaining space inside the channel hole HO_ch with the third semiconductor layer 820, the third semiconductor layer 820 may be deposited as a single layer on an inner surface of the first barrier layer 130 and used as a channel. In this case, after the third semiconductor layer 820 is formed, the remaining space inside the channel hole HO_ch (a region indicated by the dashed line) may be completely filled with an insulating layer.

The example materials that may fill the remaining space inside the channel hole HO_ch may be collectively referred to as filling materials.

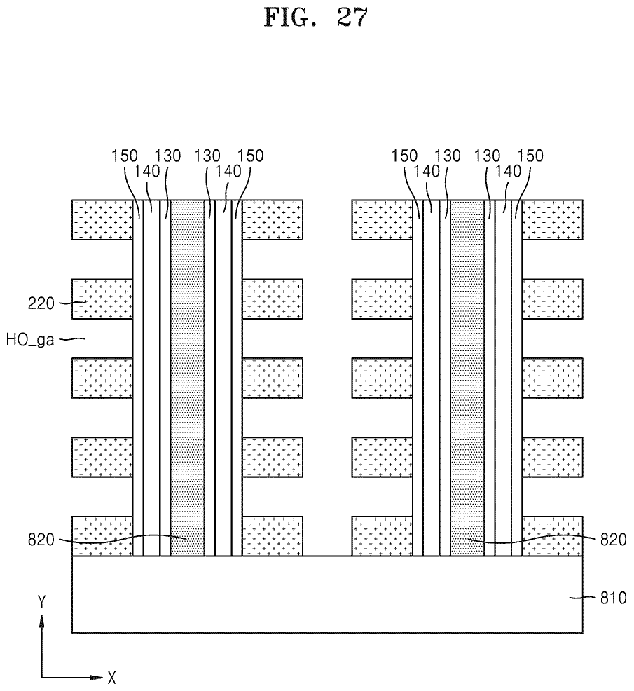

Next, as illustrated in FIG. 26, the structure illustrated in FIG. 25A is etched and cut.

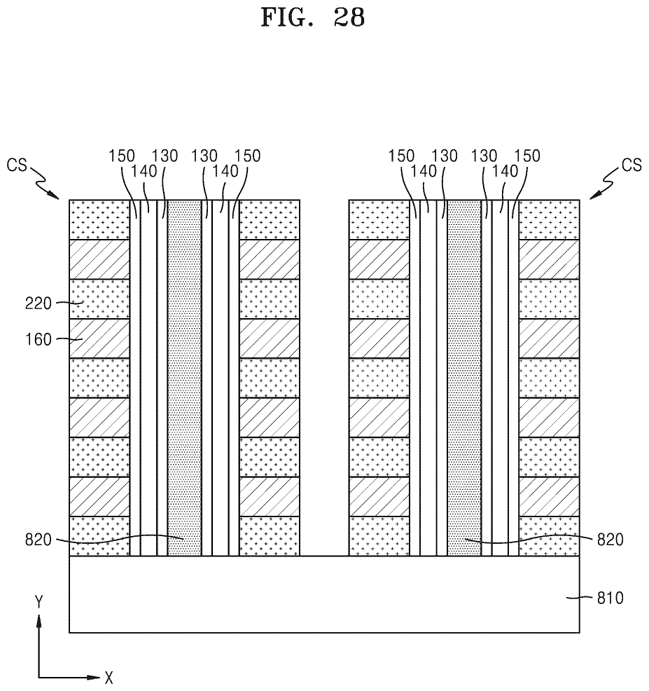

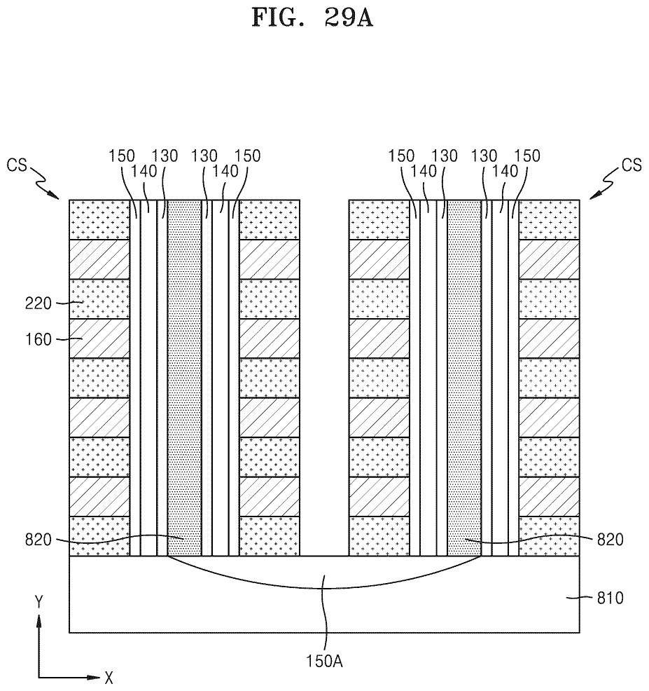

Next, as illustrated in FIG. 27, the remaining sacrificial layer 1710 is removed and a gate hole HO_ga is formed, and an electrode material is deposited on the gate hole HO_ga to form a gate electrode 160 as illustrated in FIG. 28. In this way, two string cells CS are formed on the substrate 810.

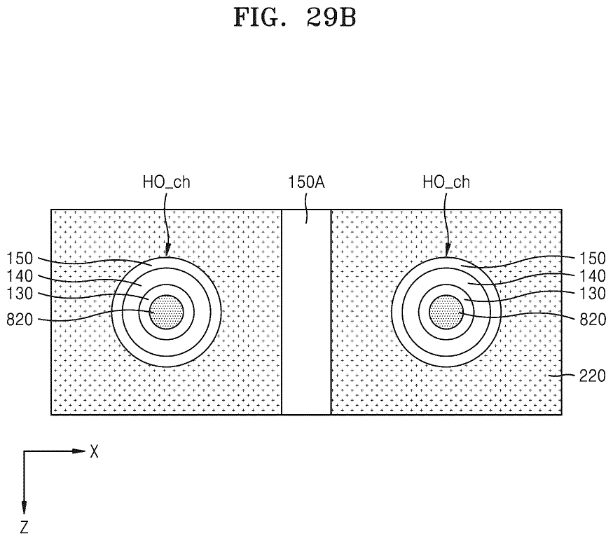

Next, as illustrated in FIGS. 29A and 29B, a fifth doped region 150A, which is a common source region, is formed in the substrate 810. The formation of the fifth doped region 150A is a process of injecting a dopant into a predetermined region on the substrate 810 to form a high-concentration region, and the fifth doped region 150A is formed in contact with the third semiconductor layer 820 of one end of the two string cells CS.

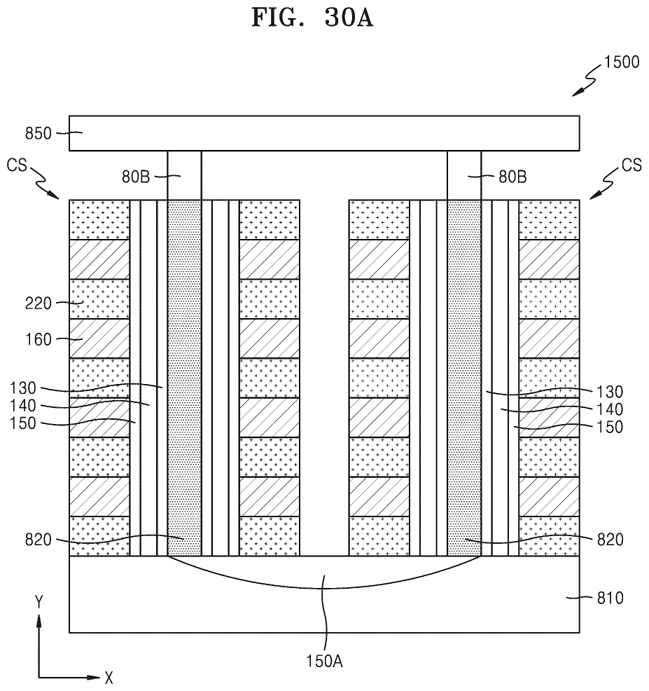

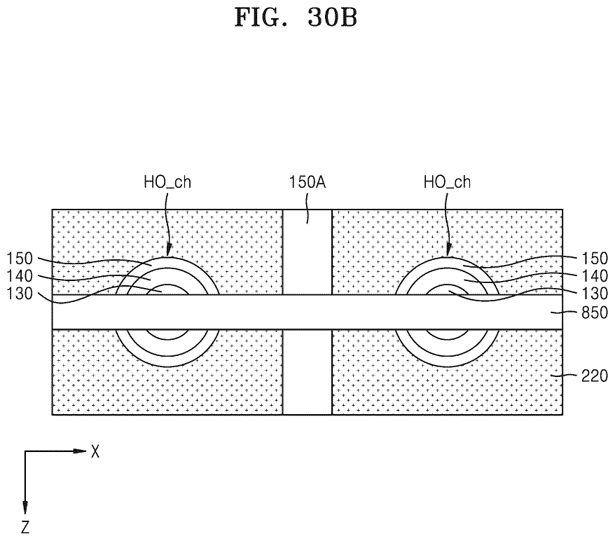

Next, as shown in FIGS. 30A and 30B, a fourth doped region 80B connected to the other end of the two string cells CS is formed, and a bit line 850 connecting the fourth doped region 80B is formed. That is, the fourth doped region 80B connected to the other end (e.g., upper end) of the third semiconductor layer 820 opposite to one end (e.g., lower end) of the third semiconductor layer 820 that contacts the fifth doped region 150A is formed, and the bit line 850 connecting the fourth doped region 80B is formed.

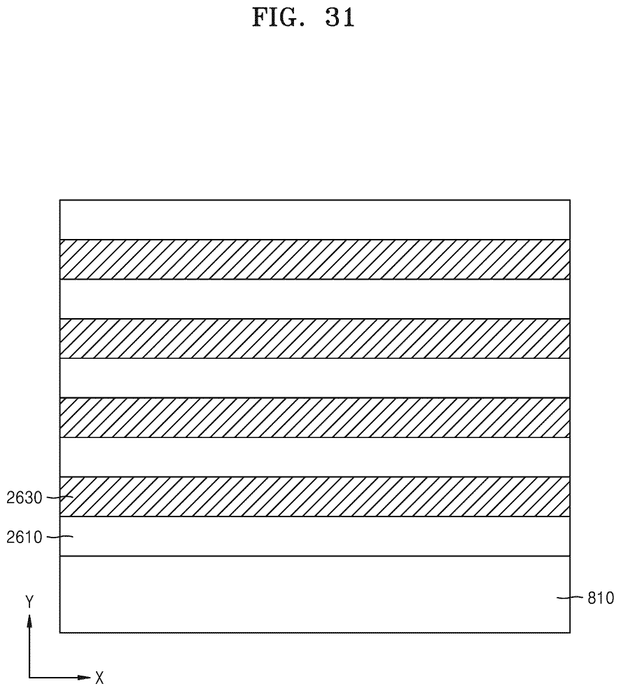

FIGS. 31 to 36 show a third manufacturing method of a nonvolatile memory device step by step, according to at least one example embodiment. FIGS. 31 to 36 may be a manufacturing method of the V-NAND illustrated in FIG. 13.

Referring to FIG. 31, a stack structure is formed by alternately and repeatedly stacking a second sacrificial layer 2610 and a first mask layer 2630 on a substrate 810. The first mask layer 2630 may be an etching mask or a photosensitive film pattern, but other masks may be used.

The second sacrificial layer 2610 is a layer for limiting a region where an insulating layer for separating a gate electrode is to be formed and may include a material having a different etching ratio from the material of the first mask layer 2630.

As shown in FIG. 31, after forming the stack structure, the second sacrificial layer 2610 is removed by following the processes from FIG. 23A to FIG. 26.

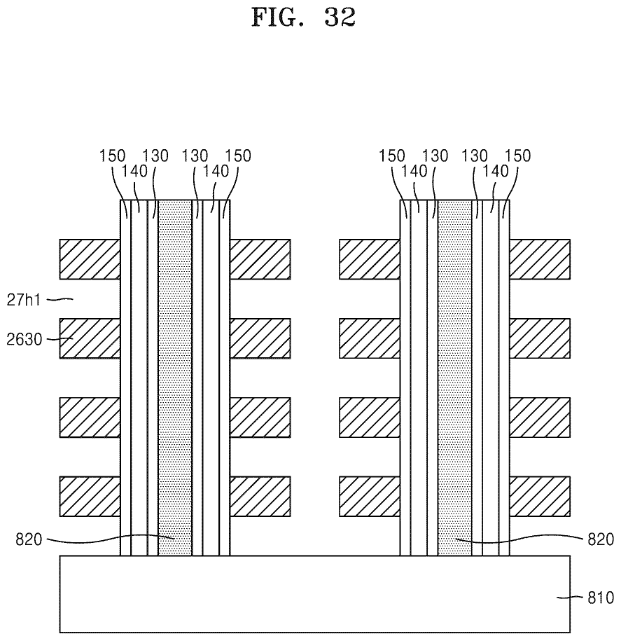

FIG. 32 shows the result of removing the second sacrificial layer (2610).

As shown in FIG. 32, when the second sacrificial layer 2610 is removed, a first hole 27h1 is formed in that location.

After the second sacrificial layer 2610 is removed, the portion exposed through the first hole 27h1 is etched. At this time, the portion covered with the first mask layer 2630 may be protected from the etching. The etching may be performed until the third semiconductor layer 820 is exposed.

In at least one example, the etching may be a continuation of the etching for removing the second sacrificial layer 2610. That is, the etching may be continued until the third semiconductor layer 820 is exposed while etching the second sacrificial layer 2610. In at least one example, the etching may use dry etching, but is not limited thereto.

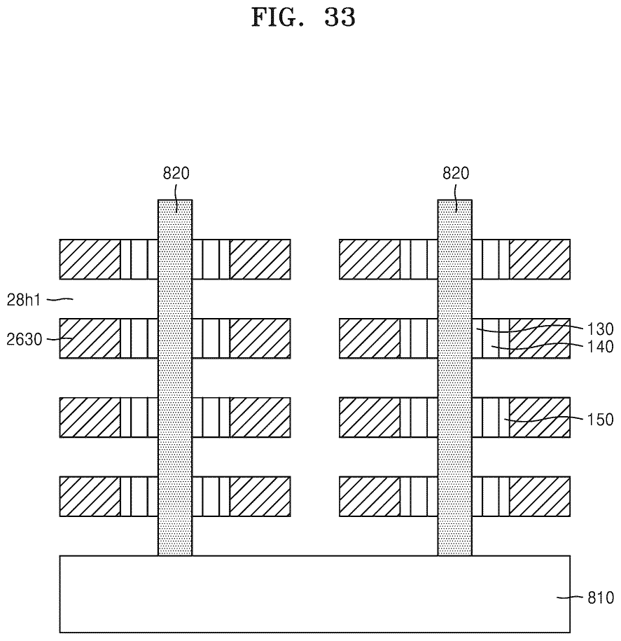

As a result of the etching, as shown in FIG. 33, the stacks formed by the first and second barrier layers 130 and 150 and the recording layer 140 are vertically spaced from each other, and the third semiconductor layer 820 between these stacks is exposed. That is, a second hole 28h1 is formed between the stacks to be filled with an insulating layer.

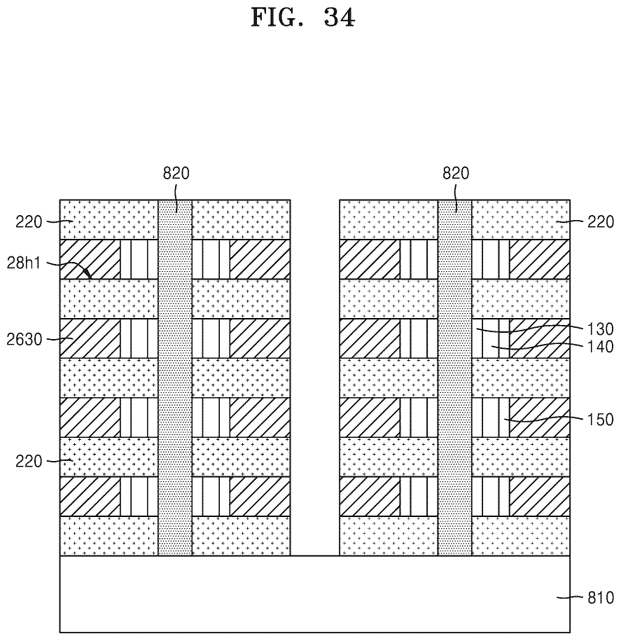

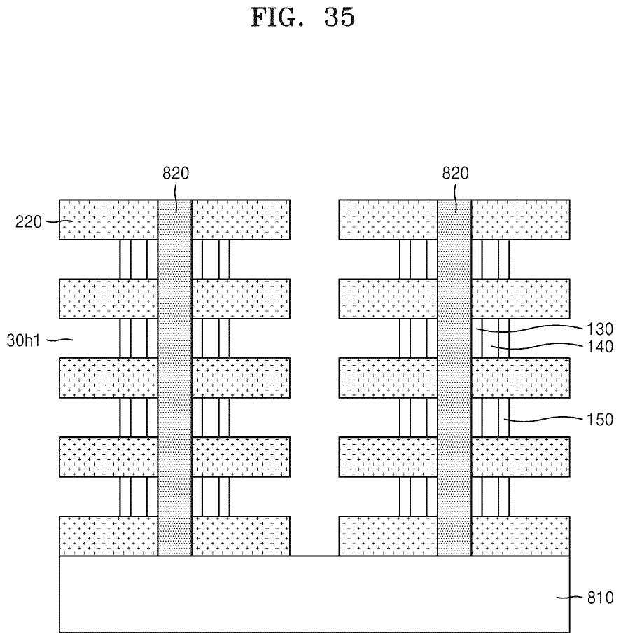

Next, as shown in FIG. 34, an insulating layer 220 is formed to fill the second hole 28h1. After the insulating layer 220 is formed, the first mask layer 2630 is removed. As the first mask layer 2630 is removed, a third hole 30h1 is formed between the insulating layers 220. The second barrier layer 150 is exposed through the third hole 30h1, as shown in FIG. 35.

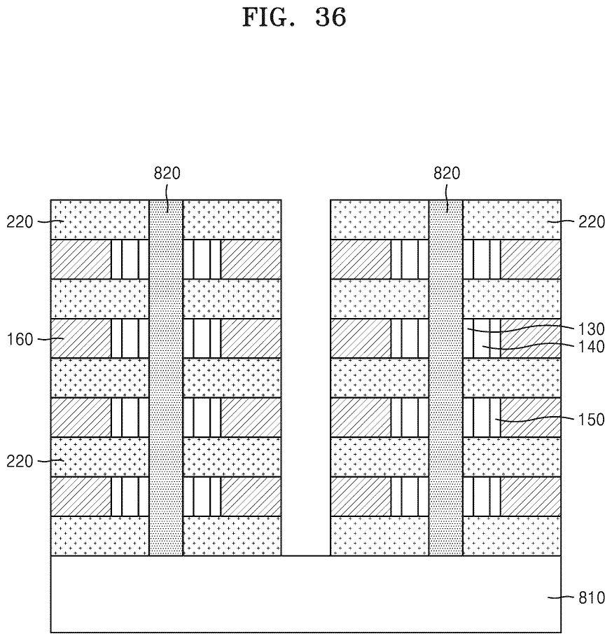

The third hole 30h1 is filled with a gate electrode layer 160, as shown in FIG. 36.

Thereafter, the process of FIGS. 29A to 30A is followed. As a result, a VNAND, in which a plurality of memory cells includes individually separated cell strings excluding the channel, may be formed.

Each of the memory devices 100, 400, 500, 800, and 1500 according to the disclosure, the second memory cell array MCA2 of FIG. 3, or the cell string CS′ shown in FIG. 13 may be employed as a memory system of various electronic apparatuses. Each of the memory devices 100, 400, 500, 800, and 1500, the second memory cell array MCA2 of FIG. 3, or the cell string CS′ shown in FIG. 13 may be implemented as a chip-shaped memory block and may be used as a neuromorphic computing platform, or may be used to configure a neural network.

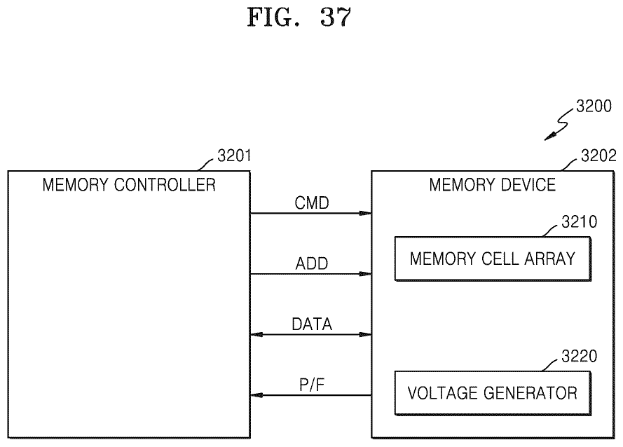

FIG. 37 is a block diagram of a memory system according to at least one example embodiment.

Referring to FIG. 37, the memory system 3200 may include a memory controller 3201 and a memory device 3202. The memory controller 3201 may perform a control operation for the memory device 3202. For example, the memory controller 3201 provides an address ADD to the memory device 3202 and a command CMD to perform programming (or writing), reading and/or erasing operations on the memory device 3202. Additionally, data for programming operations and read data may be transmitted between the memory controller 3201 and the memory device 3202.

The memory device 3202 may include a memory cell array 3210 and a voltage generator 3220. The memory cell array 3210 may include a plurality of memory cells arranged in a region where a plurality of word lines and a plurality of bit lines intersect each other. The memory cell array 3210 may include at least one of the memory devices based on the example embodiments of FIGS. 1 to 5 and FIGS. 8 to 15.

The memory controller 3201 may include a processing circuit, such as hardware including logic circuits, a hardware/software combination, such as processor execution software, or any combination thereof. For example, more specifically, the processing circuit may be a central processing unit (CPU), an arithmetic logic unit (ALU), a digital signal processor, a microcomputer, a field programmable gate array (FPGA), a system-on-chip (SoC), a programmable logic unit, a microprocessor, an application-specific integrated circuit (ASIC), etc., but is not limited thereto. The memory controller 3201 may operate in response to a request from a host (not shown). The memory controller 3201 may access the memory device 3202 and control the control operation (e.g., write/read operation) described above. Therefore, the memory controller 3201 may be converted into a special-purpose controller and configured accordingly. The memory controller 3201 may generate an address ADD and a command CMD for performing a programming/reading/erasing operation on the memory cell array 3210. In addition, in response to a command from the memory controller 3201, a voltage generator 3220 (e.g., power circuit) may generate a voltage control signal for controlling a voltage level of a word line for data programming or data reading to the memory cell array 3210.

In addition, the memory controller 3201 may perform a decision operation on data read from the nonvolatile memory device 3202. For example, the number of on-cells and/or the number of off-cells may be determined from the data read from the memory cells. The memory device 3202 may provide a pass/fail (P/F) signal to the memory controller 3201 according to the read result for the read data. The memory controller 3201 may control the write and read operations of the memory cell array 3210 by referring to a P/F signal.

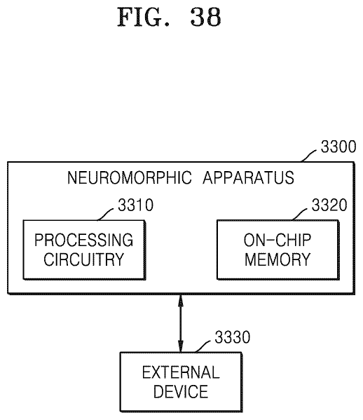

FIG. 38 is a block diagram showing a neuromorphic apparatus and an external device connected thereto, according to at least one example embodiment.

Referring to FIG. 38, the neuromorphic apparatus 3300 may include a processing circuit 3310 and/or a memory 3320. The neuromorphic apparatus 3300 may include one of the memory devices based on the example embodiments of FIGS. 1 to 5 and FIGS. 8 to 15 in the memory 3320 and/or in the processing circuit 3310.

In some embodiments, the processing circuit 3310 may be configured to control a function for driving the neuromorphic apparatus 3300. For example, the processing circuit 3310 may be configured to control the neuromorphic apparatus 3300 by executing a program stored in the memory 3320. In some embodiments, the processing circuit 3310 may include hardware such as a logic circuit, a hardware/software combination such as a processor executing software, or any combination thereof. For example, the processor may include, but is not limited to, a CPU, a graphics processing unit (GPU), an application processor (AP) included in the neuromorphic apparatus 3300, an ALU, a digital signal processor, a microcomputer, a FPGA, an SoC, a programmable logic unit, a microprocessor, an ASIC, and the like. In some embodiments, the processing circuit 3310 may be configured to read/write various data to/from the external device 3330, and/or execute the neuromorphic apparatus 3300 using the read/written data. In some embodiments, the external device 3330 may include an external memory and/or a sensor array having an image sensor (e.g., a CMOS image sensor circuit).

In some embodiments, the neuromorphic apparatus 3300 of FIG. 38 may be applied to a machine learning system. The machine learning system may utilize various artificial neural network organization and processing models, such as a convolutional neural network (CNN), a deconvolutional neural network, a recurrent neural network (RNN) optionally including a long short-term memory (LSTM) unit and/or a gated recurrent unit (GRU), a stacked neural network (SNN), a state-space dynamic neural network (SSDNN), a deep faith network (DBN), a generative adversarial network (GAN), and/or a restricted Boltzmann machine (RBM).

Alternatively, the machine learning system may include other forms of machine learning models, such as linear and/or logistic regression, statistical clustering, Bayesian classification, decision trees, dimensionality reduction such as principal component analysis, expert systems, and/or ensembles such as random forests. These machine learning models may be used to provide various services and/or applications. For example, image classification services, user authentication services based on biometric information or biometric data, advanced driver assistance system (ADAS) services, voice assistant services, automatic voice recognition (ASR) services, etc. may be executed by electronic apparatuses.

The disclosed nonvolatile memory device includes a recording layer (electrolyte layer) including mobile ions in a gate stack, and a barrier layer between the recording layer and the gate electrode and between the recording layer and the channel. Data is recorded and read by utilizing the characteristic that the distribution (arrangement) of mobile ions changes depending on the applied voltage, and thus the threshold voltage of the memory device changes.

The disclosed memory device utilizes redistribution of ions within a recording layer instead of electron tunneling in a memory operation. Because the movement of ions is relatively static compared to electrons, the disclosed memory device may avoid the problem of reduced retention characteristics due to electrons moving to a shared charge trap layer in a resistive V-NAND of the related art.

In addition, in the case of the disclosed memory device, because electron tunneling is not required in a program operation, and thus, an operating voltage may be lowered.

In addition, because the retention characteristics may be improved as described above, a gap between vertically stacked gates in a V-NAND may be narrowed, which may be advantageous for high integration, and thus, the memory capacity may be increased.

The memory device has been described with reference to the example embodiments shown in the accompanying drawings, but it will be understood by those of ordinary skill in the art that various changes in form and details may be made therein without departing from the spirit and scope of the inventive concept. While many matters have been described in detail in the above description, they should be construed as illustrative of preferred embodiments rather than to limit the scope of the invention. Therefore, the scope of the disclosure should not be defined by the embodiments described above, but should be determined by the technical spirit described in the claims.

It should be understood that the example embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

1. A memory device comprising:
a first semiconductor layer including a channel; and
a gate stack on the channel, the gate stack including
an electrolyte layer including mobile ions configured such that the gate stack has an adjustable distribution state depending on an applied voltage, and
a first barrier layer and a second barrier layer facing each other with the electrolyte layer therebetween, the first and second barrier layers configured to inhibit the mobile ions from diffusing out of the electrolyte layer.

2. The memory device of claim 1, further comprising:
a first auxiliary barrier layer between the electrolyte layer and the first barrier layer.

3. The memory device of claim 2, further comprising:
a second auxiliary barrier layer between the electrolyte layer and the second barrier layer.

4. The memory device of claim 1, further comprising:
a third auxiliary barrier layer facing the electrolyte layer with the first barrier layer therebetween.

5. The memory device of claim 4, further comprising:
a fourth auxiliary barrier layer facing the electrolyte layer with the second barrier layer therebetween.

6. The memory device of claim 1, wherein the mobile ions include alkali metal ions, alkali-earth metal ions, or a combination thereof.

7. The memory device of claim 1, further comprising:
a second semiconductor layer,
wherein the first semiconductor layer is provided in a direction perpendicular to one surface of the second semiconductor layer,
the gate stack is included in a plurality of the gate stacks, and the plurality of gate stacks are stacked in the direction perpendicular to the one surface of the second semiconductor layer, and
the channel is shared by the plurality of gate stacks.

8. The memory device of claim 7, wherein the first barrier layer, the second barrier layer, and the electrolyte layer of each of the plurality of gate stacks are connected to the first barrier layer, the second barrier layer, and the electrolyte layer of a neighboring gate stack in the direction perpendicular to the one surface of the second semiconductor layer.

9. The memory device of claim 7, wherein the first barrier layer, the second barrier layer, and the electrolyte layer of each of the plurality of gate stacks are spaced apart from the first barrier layer, the second barrier layer, and the electrolyte layer of a neighboring gate stack in the direction perpendicular to the one surface of the second semiconductor layer.

10. The memory device of claim 7, wherein each of the plurality of gate stacks completely surrounds the first semiconductor layer, and
the first barrier layer, the electrolyte layer, and the second barrier layer are concentric.

11. A method of manufacturing a memory device, the method comprising:
forming a stack structure by alternately depositing a plurality of sacrificial layers and insulating layers;
forming a channel hole penetrating the stack structure;
sequentially forming a first barrier layer, an electrolyte layer including mobile ions, and a second barrier layer on an inner surface of the channel hole;
filling at least a portion of an interior of the channel hole, remaining after the first barrier layer, the electrolyte layer, and the second barrier layer are formed, with a semiconductor layer;
removing the sacrificial layers to form gate holes; and
depositing an electrode material in the gate holes.

12. The method of claim 11, further comprising:
forming a first auxiliary barrier layer such that the first auxiliary barrier layer is between the electrolyte layer and the first barrier layer.

13. The method of claim 12, further comprising:
forming a second auxiliary barrier layer such that the second auxiliary barrier layer is between the electrolyte layer and the second barrier layer.

14. The method of claim 11, further comprising:
forming a third auxiliary barrier layer such that the third auxiliary barrier layer is between the semiconductor layer and the first barrier layer.

15. The method of claim 14, further comprising:
forming a fourth auxiliary barrier layer such that the fourth auxiliary barrier layer is between the electrode material and the second barrier layer.

16. The method of claim 11, wherein the mobile ions include alkali metal ions, alkali-earth metal ions, or a combination thereof.

17.-19. (canceled)

20. An electronic apparatus comprising:
a memory; and
a memory controller configured to control an operation of the memory,
wherein the memory comprises
a first semiconductor layer including a channel, and
a gate stack on the channel of the first semiconductor layer, the gate stack including an electrolyte layer including mobile ions configured such that the gate stack has an adjustable distribution state depending on an applied voltage, and a first barrier layer and a second barrier layer facing each other with the electrolyte layer therebetween, the first and second barrier layers configured to inhibit the mobile ions from diffusing out of the electrolyte layer.
